(19) United States
(12) Patent Application Publication
(10) Pub. No.: US 2016/0277023 A1
(43) Pub. Date: Sep. 22, 2016

(54) ELECTROSTATIC SWITCH CONTROLLER, CONTROL METHOD THEREOF, DOOR OPERATING DEVICE, AND ELECTRONIC KEY SYSTEM

(71) Applicant: Rohm Co., Ltd., Kyoto (JP)

(72) Inventor: Masao Nakajima, Kyoto (JP)

(21) Appl. No.: 15/067,329

(22) Filed: Mar. 11, 2016

(30) Foreign Application Priority Data
Mar. 17, 2015 (JP) 2015053343

(51) Int. Cl. H03K 17/96; E05B 81/56; E05F 15/75; E05F 15/60; E05F 15/71

(52) U.S. Cl. CPC H03K 17/962; E05F 15/60; E05F 15/71; E05F 15/75; E05B 81/56; E05B 81/77

(57) ABSTRACT

An electrostatic switch controller, comprising: a contact sensing sensor configured to sense presence of contact of a person to a contact portion when the person performs an operation; a pressure sensing sensor configured to sense a pressure applied to the contact portion; and a control part configured to determine whether the contact to the contact portion is made by at least a portion of a body of the person, based on a result of the sensing by the contact sensing sensor and the pressure sensing sensor.

### CROSS-REFERENCE TO RELATED APPLICATION(S)

This application is based upon and claims the benefit of priority from Japanese Patent Application No. 2015-053343, filed on Mar. 17, 2015, the entire contents of which are incorporated herein by reference.

### TECHNICAL FIELD

The present disclosure relates to an electrostatic switch controller, a control method thereof, a door operating device, and an electronic key system.

### BACKGROUND

Locks of houses or apartments or door locks of vehicles can be opened and closed by means of wireless communication with keys of cards or smartphones. A person who has a key can open/close a lock without touching a door knob or a door handle, that is, without taking out the key when the person carries the key.

In addition, there has been disclosed a vehicle door handle device called a smart key system or a smart entry system, which uses an electrostatic capacitance type lock sensor electrode and unlock sensor electrode.

However, for a lock of a house or a door lock of a vehicle, there is a case where it is rather undesirable to easily unlock the lock only with a key.

For example, in a vehicle door handle device, called a “smart key system” or “smart entry system,” which uses an electrostatic switch such as an electrostatic capacitance type lock sensor electrode and unlock sensor electrode in, since a change in stray capacitance occurring between the lock sensor electrode and a human body is detected, it is difficult to distinguish attachment of water from contact by a person. In such a vehicle door handle device, if water droplets having substantially the same relative dielectric constant (e5=80) as a human body are attached to the portion determining whether a lock is opened or closed (the portion detecting a change in stray capacitance), it is determined that the attached droplet is analogous to contact by a person and the door lock is accordingly released. An exemplary source of such water droplets may include rainfall, a stream of water during car washing, and the like.

Furthermore, such an electrostatic switch cannot sense the degree of contact to the sensor electrode (for example, the magnitude of pressure (pressing) applied to the sensor electrode), although it may sense the presence of contact to the sensor electrode (i.e., whether or not something contacts the sensor electrode). This makes it difficult to perform fine operations and advanced setting in accordance with a degree of contact to the sensor electrode, which has been considered to be user-unfriendly. If it becomes possible to detect the magnitude of the pressure (pressing) applied to the sensor electrode as well as the presence of contact to the sensor electrode, it is possible to more accurately sense whether something contacting the sensor electrode is water such as raindrops, or a human body (for example, a finger).

### SUMMARY

The present disclosure provides some embodiments of an electrostatic switch controller, a control method thereof, a door operating device, and an electronic key system, which are capable of sensing contact (approach) with an electrostatic switch and a degree of pressing (pressure) against the electrostatic switch at once while preventing erroneous sensing due to water droplets or the like attached to the electrostatic switch.

According to one embodiment of the present disclosure, there is provided an electrostatic switch controller including: a contact sensing sensor configured to sense the presence of contact of a person to a contact portion when the person performs an operation; a pressure sensing sensor configured to sense a pressure applied to the contact portion; and a control part configured to determine whether the contact to the contact portion is a contact of at least a portion of a body of the person to the contact portion, based on a result of the sensing by the contact sensing sensor and the pressure sensing sensor.

According to another embodiment of the present disclosure, there is provided a control method of an electrostatic switch controller including a contact sensing sensor configured to sense the presence of contact of a person to a contact portion when the person performs an operation, a pressure sensing sensor configured to sense a pressure applied to the contact portion, and a control part configured to determine whether the contact to the contact portion is a contact of at least a portion of a body of the person to the contact portion, based on a result of the sensing by the contact sensing sensor and the pressure sensing sensor, the control method including: by the contact sensing sensor, sensing the presence of contact to the contact portion; by the pressure sensing sensor, sensing a pressure applied to the contact portion; and, by the control part, determining whether the contact to the contact portion is a contact of at least a portion of a body of the person to the contact portion, based on a result of the sensing by the contact sensing sensor and the pressure sensing sensor.

According to another embodiment of the present disclosure, there is provided a door operating device including: an electrostatic switch controller including a contact sensing part including a contact sensing sensor which senses the presence of contact of a person to a contact portion when the person performs an opening/closing operation for a door and a pressure sensing sensor which senses a pressure applied to the contact portion; a locking part configured to unlock and lock the door; and a control part configured to instruct the locking part to unlock the door when determining that the contact to the contact portion is a contact of at least a portion of a body of the person to the contact portion, based on a result of the sensing by the contact sensing sensor and the pressure sensing sensor.

According to another embodiment of the present disclosure, there is provided an electronic key system including: an electrostatic switch controller including a contact sensing part including a contact sensing sensor which senses the presence of contact of a person to a contact portion when the person performs an opening/closing operation for a door, and a pressure sensing sensor which senses a pressure applied to the contact portion; a locking part configured to unlock and lock the door; a transmitter configured to form a sensing range of an electronic key carried by the person; and a control part configured to recognize the electronic key falling within the sensing range and an operation of the electronic key and instruct the locking part to unlock the door when determining that the contact to the contact portion is a contact of at least a portion of a body of the person to the contact portion, based on a result of the sensing by the contact sensing sensor and the pressure sensing sensor.

### BRIEF DESCRIPTION OF THE DRAWINGS

FIG. 1 is a schematic block diagram illustrating the configuration of a door operating device provided with an electrostatic switch controller, according to an embodiment.

FIGS. 2A and 2C are schematic top views illustrating examples of electrodes of a contact-only sensing electrostatic switch, where FIG. 2A shows an example of basic-sized electrodes, FIG. 2B shows an example of small-sized electrodes and FIG. 2C shows an example of large-sized electrodes.

FIG. 3A is a schematic view illustrating an exemplary operation of the electrostatic switch having the small-sized electrodes illustrated in FIG. 2B and FIG. 3B is a schematic view illustrating an exemplary operation of the electrostatic switch having the large-sized electrodes illustrated in FIG. 2C.

FIG. 4A is a top view schematically illustrating an exemplary operation of the electrostatic switch illustrated in FIG. 3A, FIG. 4B is a schematic sectional structural view taken along line I-I in FIG. 4A, illustrating a situation where a finger is spaced apart (close) from the electrodes, and FIG. 4C is a schematic sectional structural view taken along line I-I in FIG. 4A, illustrating a situation where the finger contacts the electrodes.

FIGS. 5A and 5D are schematic sectional structural views showing an example of a pressure sensing electrostatic switch used for the electrostatic switch controller according to the embodiment, FIG. 5A schematically illustrating a situation where a finger is spaced apart from (approaching) a conductive rubber formed on an electrode, FIG. 5B schematically illustrating a situation where the finger makes contact with the conductive rubber, FIG. 5C schematically illustrating a situation where the finger presses against the conductive rubber weakly (with a small pressure), and FIG. 5D schematically illustrating a situation where the finger presses against the conductive rubber strongly (with a large pressure).

FIG. 6A is a schematic perspective view illustrating an electrostatic switch in which a conductive rubber having substantially the same size as the small-sized electrodes is formed on the electrodes and a current J flows in an arrow direction and FIG. 6B is a schematic perspective view illustrating an electrostatic switch in which a current J flows in the direction opposite to the direction of current flow in the electrostatic switch illustrated in FIG. 6A.

FIG. 7A is a schematic sectional structural view illustrating a situation where a finger makes contact with the conductive rubber of the electrostatic switch illustrated in FIGS. 6A and 6B and FIG. 7B is a schematic sectional structural view for explaining an example of a current flowing under a state where the finger presses against the conductive rubber of the electrostatic switch illustrated in FIGS. 6A and 6B.

FIG. 8A is a schematic top view showing an example where a conductive rubber is formed on large-sized electrodes and a wiring electrode is connected to the conductive rubber, FIG. 8B is a schematic sectional structural view taken along line II-II in FIG. 8A and FIG. 8C is a schematic sectional structural view taken along line in FIG. 8A.

FIG. 9A is a schematic top view illustrating a situation where a finger presses against the conductive rubber of the electrostatic switch illustrated in FIG. 8A, FIG. 9B is a schematic sectional structural view taken along line IV-IV in FIG. 9A, FIG. 9C is a schematic sectional structural view taken along line v-v in FIG. 9A, FIG. 9D is a schematic view illustrating a non-conduction state in which the finger makes no contact with the conductive rubber, and FIG. 9E is a schematic view illustrating a conduction state in which the finger presses against the conductive rubber.

FIG. 10 is a schematic block diagram showing an example where a pad electrode for sensing a contact to an electrostatic switch and a pad electrode for sensing a pressure for the electrostatic switch are shared for the electrostatic switch controller according to the embodiment.

FIG. 11 is a schematic block diagram showing an example of a capacitance detected when a finger is in contact with an electrostatic switch and a current detected when the finger presses against the electrostatic switch in the electrostatic switch controller according to the embodiment.

FIG. 12 shows one example of an electrode pattern that shares electrodes in the electrostatic switch controller according to the embodiment.

FIG. 13 shows another example of the electrode pattern that shares electrodes in the electrostatic switch controller according to the embodiment.

FIG. 14 is a schematic flowchart illustrating a procedure for controlling the electrostatic switch controller according to the embodiment.

FIG. 15 is a schematic external view of an example of a door handle having a door operating device including the electrostatic switch controller according to the embodiment.

FIG. 16A is a schematic perspective view illustrating the rear side of the door handle illustrated in FIG. 15 and FIG. 16B is a partially-enlarged view of the rear side of the door handle illustrated in FIG. 15.

FIG. 17 is a schematic perspective view illustrating a vehicle equipped with a door operating device according to Modification 1 of the embodiment and further equipped with a raindrop sensing sensor located in the upper portion of the front of the vehicle.

FIG. 18 is a schematic external view of a door handle equipped with a door operating device according to Modification 2 of the embodiment.

FIG. 19 is a schematic view illustrating a situation where the door handle provided with the door operating device according to the embodiment is operated with a right hand.

FIG. 20 is a schematic perspective view illustrating a contact sensing part in the rear side of a door handle according to Modification 3 of the embodiment.

FIG. 21 is a schematic perspective view illustrating a contact sensing part in the rear side of a door handle according to Modification 4 of the embodiment.

FIG. 22 is a schematic external view of a door handle having a door operating device according to Modification 5 of the embodiment.

FIG. 23 is a schematic block diagram showing one example of an application circuit configuration of the electrostatic switch controller according to the embodiment.

FIG. 24 is a schematic block diagram showing another example of the application circuit configuration of the electrostatic switch controller according to the embodiment.

FIGS. 25A and 25B are schematic views illustrating a situation of operating a vehicle equipped with a general keyless entry system, where FIG. 25A illustrates an exemplary door opening operation and FIG. 25B illustrates an exemplary engine starting operation.

FIGS. 26A and 26B are schematic views illustrating a situation of operating a vehicle equipped with a general electronic key system, where FIG. 26A illustrates an exemplary door opening operation and FIG. 26B illustrates an exemplary engine starting operation.

FIG. 27A is a schematic view illustrating a situation of operating a vehicle equipped with an electronic key system according to a comparative example and FIG. 27B is a schematic view illustrating a situation of operating the vehicle equipped with the electronic key system according to the embodiment.

FIG. 28A is a schematic perspective view illustrating a remote door lock system in a vehicle equipped with the electronic key system according to the embodiment and FIG. 28B is a schematic block diagram showing an exemplary configuration of the remote door lock system illustrated in FIG. 28A.

FIG. 29A is a schematic view illustrating a situation of operating a vehicle equipped with the electronic key system according to the embodiment, FIG. 29B is a schematic view illustrating a situation of operating a door handle of the vehicle illustrated in FIG. 29A and FIG. 29C is a schematic view illustrating a situation of operating a button switch installed in the door handle illustrated in FIG. 29B.

FIG. 30 is a schematic block diagram showing an exemplary configuration of the electronic key system according to the embodiment.

FIG. 31 is a schematic perspective view showing one example of a vehicle equipped with various parts of the electronic key system illustrated in FIG. 30.

FIG. 32 is a schematic top view showing an exemplary sensing range of the electronic key system illustrated in FIG. 30.

FIG. 33 is a schematic block diagram showing an exemplary control at the time of unlocking the door in the electronic key system illustrated in FIG. 30.

FIG. 34 is a schematic block diagram showing an exemplary control at the time of locking the door in the electronic key system illustrated in FIG. 30

### DETAILED DESCRIPTION

Embodiments of the present disclosure will now be described in detail with reference to the drawings. Throughout the drawings, the same or similar elements are denoted by the same or similar reference numerals. It is however noted that the drawings are just schematic and relationships between thickness and planar dimension of elements, thickness ratios of various layers and so on may be unrealistic. Accordingly, detailed thickness and dimensions should be determined in consideration of the following description. In addition, it is to be understood that the figures include different dimensional relationships and ratios.

The following embodiments are provided to illustrate devices and methods to embody the technical ideas of the present disclosure and are not limited to materials, forms, structures, arrangements and so on of elements detailed herein. The embodiments of the present disclosure may be modified in different ways without departing from the spirit and scope of the invention defined in the claims.

### Embodiments

### Block Configuration of Door Operating Device

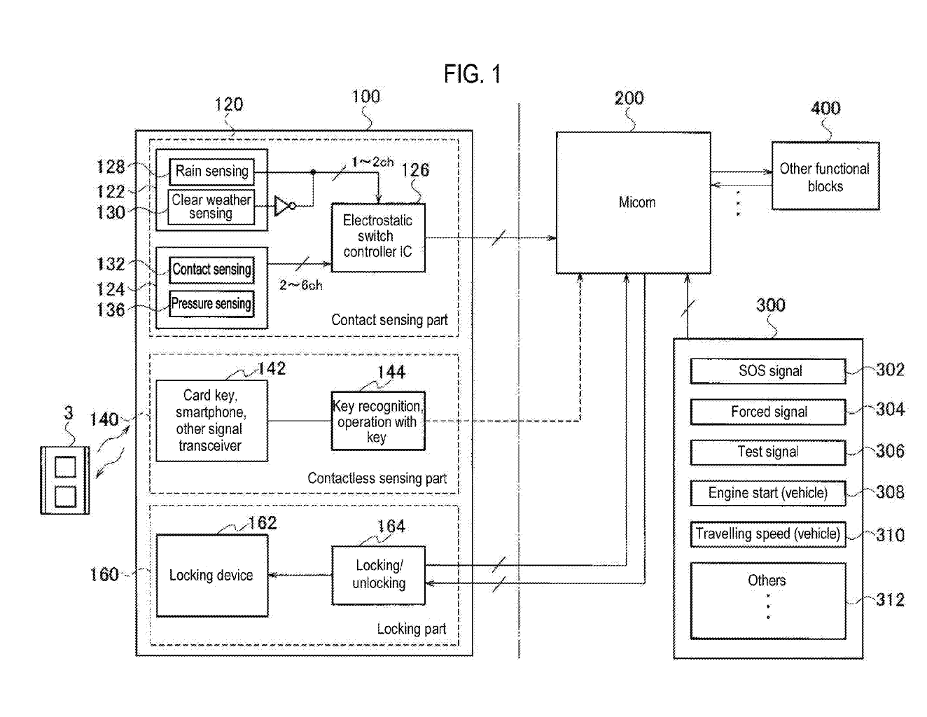

FIG. 1 is a schematic block diagram illustrating the configuration of a door operating device according to an embodiment.

A door operating device according to an embodiment includes an opening/closing mechanism part 100, other sensing part 300, other functional part 400 and a control part (microcomputer) 200 for controlling the above-mentioned parts. The opening/closing mechanism part 100 includes a contact sensing part (electrostatic switch controller) 120, a contactless sensing part 140 and a locking part 160. The other sensing part 300 includes an SOS signal sensing part 302, a forced signal sensing part 304, a test signal sensing part 306, an engine start sensing part 308, a travelling speed sensing part 310 and other sensing parts 312. The engine start sensing part 308 and the travelling speed sensing part 310 are optionally used when the door operating device according to the embodiment is applied to a transporting means such as a vehicle.

The contact sensing part 120 includes, for example, a raindrop sensing sensor (sensing electrode) 122 and a human body sensing sensor (sensing electrode) 124, each of which consists of a sensing electrode for electrostatic switch operation, such as an electrostatic capacitance sensor for sensing electrostatic capacitance, and an electrostatic switch control IC 126 for controlling the raindrop sensing sensor 122(1 to 2ch) and the human body sensing sensor 124(2 to 6ch). The raindrop sensing sensor 122 includes a rain sensing sensor (sensing electrode) 128 and a clear weather sensing sensor (sensing electrode) 130 and the human body sensing sensor 124 includes a contact sensing sensor (sensing electrode) 132 and a pressure sensing sensor (sensing electrode) 136. The contact sensing sensor 132 senses the presence of contact of at least a portion (such as a hand or a finger) of a person's body to a contact portion when the person opens/closes a door. The pressure sensing sensor 136 senses a pressure applied by at least the portion (such as a hand or a finger) of the person's body to the contact portion.

Based on results of the sensing by the contact sensing sensor 132 and the pressure sensing sensor 136, upon determining that the contact portion is contacted by at least the portion of the person's body the control part 200 instructs the locking part 160 to unlock the door.

The contactless sensing part 140 includes a signal transmitting/receiving section (signal transceiver) 142 for transmitting/receiving a signal to/from an electronic key 3 such as a card key or a smart phone, and a key recognizing section 144 for recognizing the key or an operation thereof based on the signal transmitted/received by the signal transmitting/receiving section 142.

The locking part 160 includes a locking section (locking device) 162 for locking/unlocking the door, and a locking control section 164 for controlling the lock/unlock of the locking section 162 based on a sensing signal (data) sensed by the contact sensing part 120, the contactless sensing part 140, the other sensing part 300 or the like.

The other functional part 400 is provided with various functions, including an air conditioning function, a navigation function, an audio/video function, a lighting function and so on, which can be controlled based on the sensing signal (data) sensed by the contact sensing part 120, the contactless sensing part 140, the other sensing part 300 or the like.

### (Electrostatic Switch)

### (Contact-Only Sensing Electrostatic Switch)

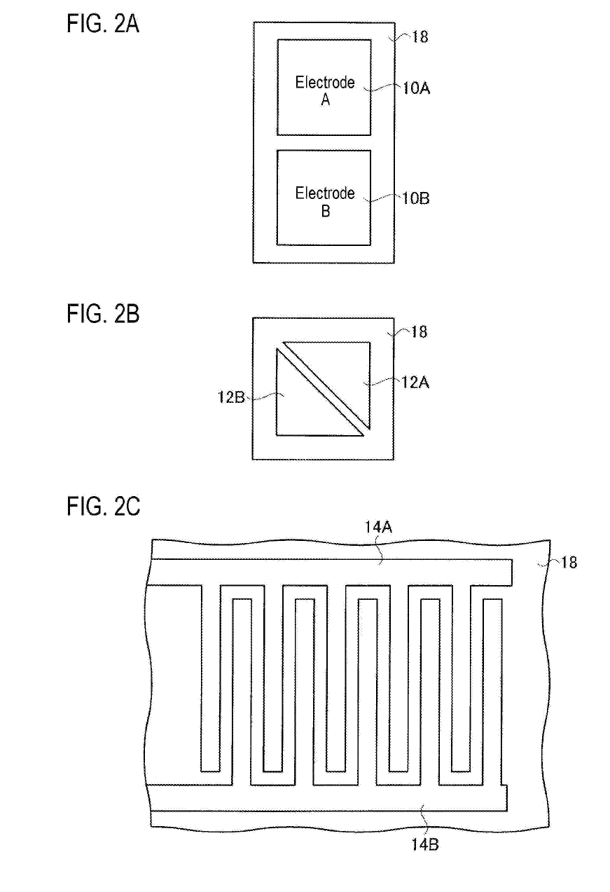

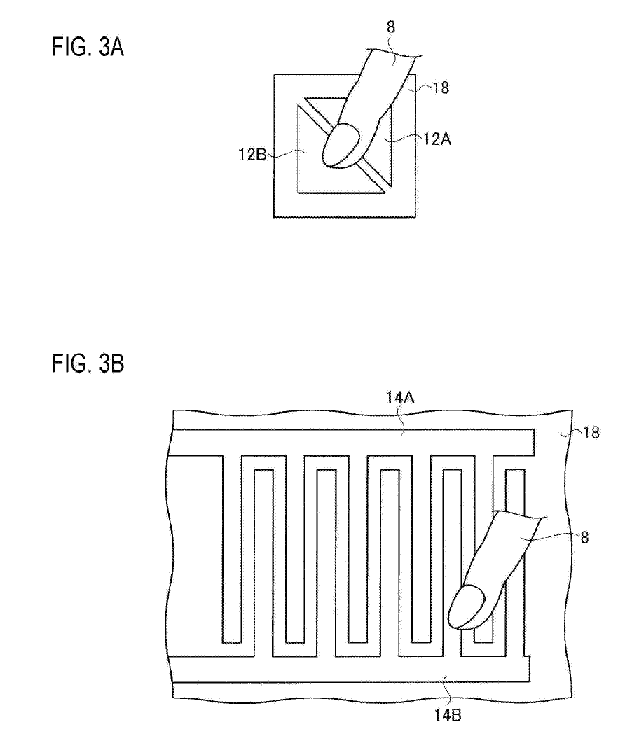

FIGS. 2A and 2B schematically show examples of electrodes of a contact-only sensing electrostatic switch. FIG. 2A shows an example of an electrostatic switch having basic-sized electrodes 10A and 10B formed on a substrate 18. FIG. 2B shows an example of an electrostatic switch having small-sized electrodes 12A and 12B formed on the substrate 18. FIG. 2C shows an example of an electrostatic switch having large-sized electrodes 14A and 14B formed on the substrate 18.

FIG. 3A is a schematic view illustrating an exemplary operation of the electrostatic switch having the small-sized electrodes illustrated in FIG. 2B. FIG. 3B is a schematic view illustrating an exemplary operation of the electrostatic switch having the large-sized electrodes illustrated in FIG. 2C is.

When the electrostatic switch illustrated in FIG. 2B is operated by a person, a finger 8 or the like contacts (or presses) the electrodes 12A and 12B, as illustrated in FIG. 3A. Similarly, when the electrostatic switch illustrated in FIG. 2C is operated by the person, the finger 8 or the like contacts (or presses) the electrodes 14A and 14B, as illustrated in FIG. 3B. The substrate 18 used herein may be a printed circuit board (PCB) or the like.

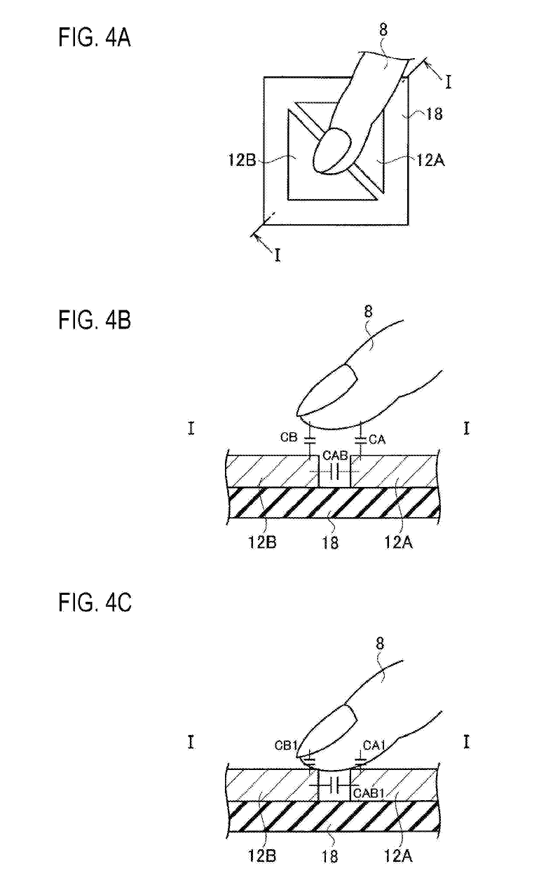

FIG. 4A is a top view schematically illustrating an exemplary operation of the electrostatic switch illustrated in FIG. 3A. FIG. 4B is a schematic sectional structural view taken along line I-I in FIG. 4A, illustrating a situation where the finger 8 is spaced apart (close) from the electrodes 12A and 12B. FIG. 4C is a schematic sectional structural view taken along line I-I in FIG. 4A, illustrating a situation where the finger 8 contacts the electrodes 12A and 12B.

As illustrated in FIGS. 4A and 4C, when the electrostatic switch having the small-sized electrodes 12A and 12B is operated with the finger 8, under a state where the finger 8 makes no contact with the electrodes 12A and 12B (see FIG. 4B), a detection capacitance between the electrode 12A and the electrode 12B is denoted by a symbol “CAB” and an electrostatic capacitance between the finger 8 and the electrode 12A and an electrostatic capacitance between the finger 8 and the electrode 12B are denoted by symbols “CA” and “CB,” respectively. Under a state where the finger 8 makes contact with the electrodes 12A and 12B (see FIG. 4C), a detection capacitance between the electrode 12A and the electrode 12B is denoted by a symbol “CAB1” and an electrostatic capacitance between the finger 8 and the electrode 12A and an electrostatic capacitance between the finger 8 and the electrode 12B are denoted by symbols “CA1” and “CB1,” respectively. Then, by detecting a change in the detection capacitance value from CAB to CAB1 (or a change from CAB1 to CAB) or sensing a change in the capacitances CA, CB, CA1 and CB1, it is possible to sense the presence of contact of the finger 8 to the electrostatic switch.

### (Electrostatic Switch According to Embodiment)

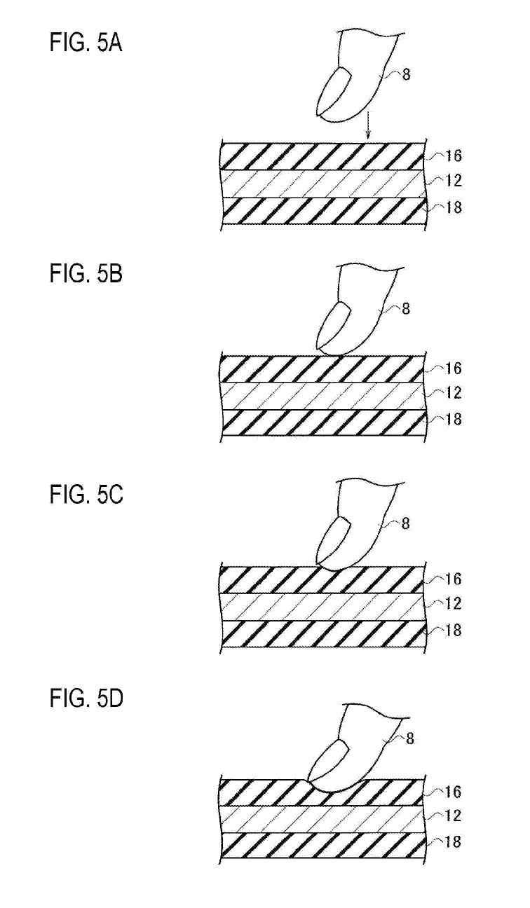

FIGS. 5A and 5D schematically show an example of a pressure sensing electrostatic switch used for the human body sensing sensor 124 or the like of the door operating device illustrated in FIG. 1. The pressure sensing electrostatic switch includes an electrode 12 formed on a substrate 18, and a conductive rubber 16 formed on the electrode 12. FIG. 5A schematically illustrates a situation where a finger 8 is spaced apart from (approaching) the conductive rubber 16 formed on the electrode 12. FIG. 5B schematically illustrates a situation where the finger 8 makes contact with the conductive rubber 16. FIG. 5C schematically illustrates a situation where the finger 8 presses against the conductive rubber 16 weakly (with a small pressure). FIG. 5D schematically illustrates a situation where the finger 8 presses against the conductive rubber 16 strongly (with a large pressure). The conductive rubber 16 is formed on the electrode 12 by means of lamination or deposition so as to cover the electrode 12.

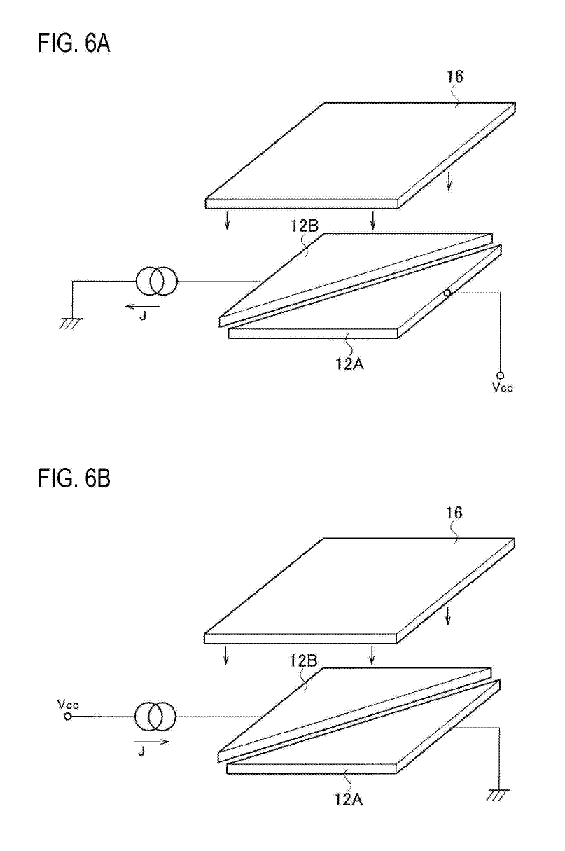

FIG. 6A illustrates an electrostatic switch in which a conductive rubber 16 having substantially the same size as the small-sized electrodes 12A and 12B formed on the substrate 18 is formed on the electrodes 12A and 12B and a current J flows in an arrow direction. FIG. 6B illustrates an electrostatic switch in which a current J flows in the direction opposite to the direction of current flow in the electrostatic switch illustrated in FIG. 6A.

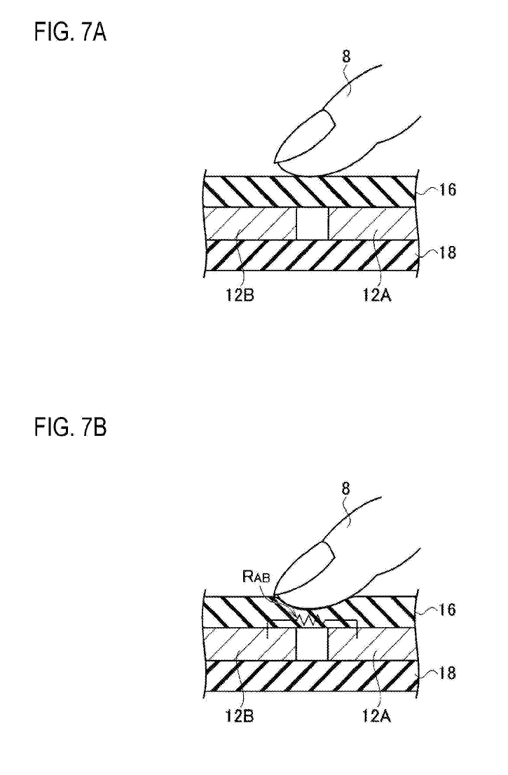

FIG. 7A is a schematic sectional structural view illustrating a situation where a finger 8 makes contact with the conductive rubber 16 of the electrostatic switch illustrated in FIGS. 6A and 6B. FIG. 7B is a schematic sectional structural view for explaining an example of a current flowing under a state where the finger presses against the conductive rubber 16 of the electrostatic switch illustrated in FIGS. 6A and 6B. Only the contact of the finger 8 with the conductive rubber 16 of the above-configured electrostatic switch cannot allow a current to flow between the electrode 12A, the conductive rubber 16 and the electrode 12B (see FIG. 7A). On the other hand, as shown in FIG. 7B, when the finger 8 presses against the conductive rubber 16 (with pressure), a current is allowed to flow between the electrode 12A, the conductive rubber 16 and the electrode 12B (with a resistance R_{AB} in this case). Then, by detecting the size of this resistance R_{AB}, it is possible to sense a pressure applied to the conductive rubber 16 (a degree of press of the conductive rubber 16 with the finger 8).

Moreover, the method for detecting the resistance RAB may include a method for measuring current flow between the electrode 12A, the conductive rubber 16 and the electrode 12B, as described above, and a method for measuring a resistance voltage division ratio of a resistance connected between an electrode and a ground (GND) or between an electrode and a power supply voltage VDD and the conductive rubber 16.

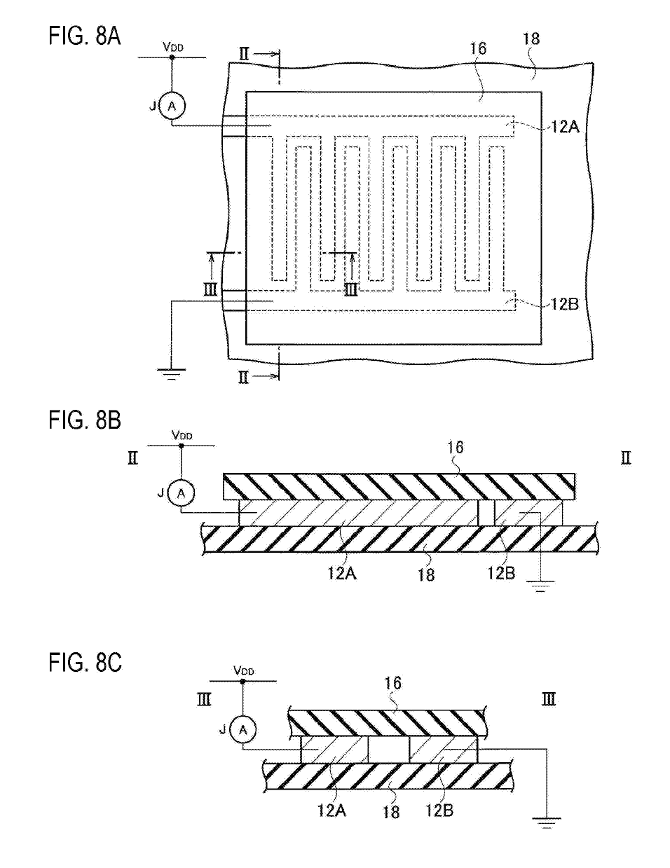

FIG. 8A is a top view schematically showing an example where a conductive rubber 16 is formed on large-sized electrodes 14A and 14B and a wiring electrode is connected to the conductive rubber 16. FIG. 8B is a schematic sectional structural view taken along line II-II in FIG. 8A. FIG. 8C is a schematic sectional structural view taken along line in FIG. 8A.

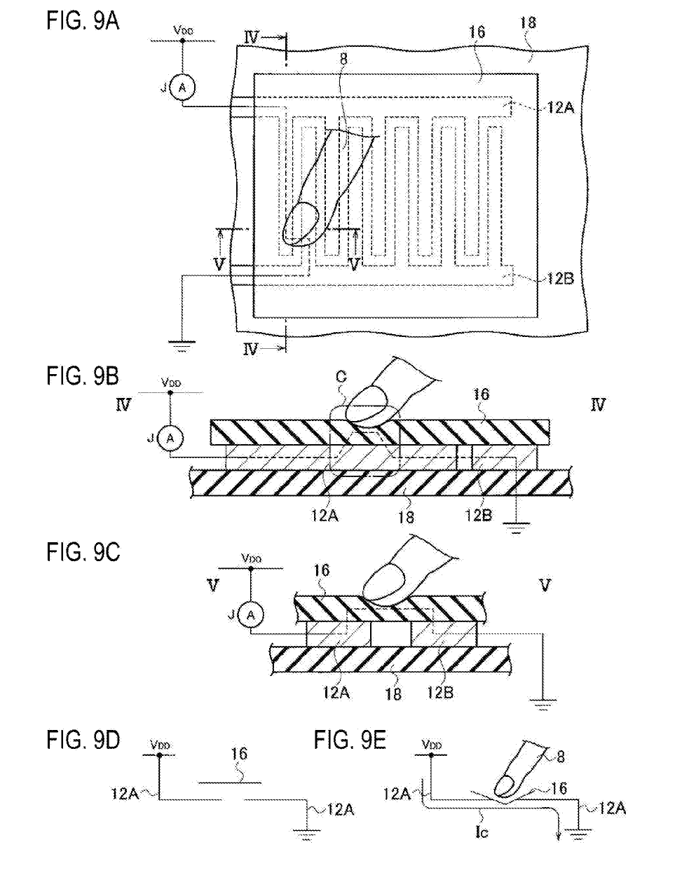

FIG. 9A is a schematic top view illustrating a situation where a finger 8 presses against the conductive rubber 16 of the electrostatic switch illustrated in FIG. 8A. FIG. 9B is a schematic sectional structural view taken along line Iv-Iv in FIG. 9A. FIG. 9C is a schematic sectional structural view taken along line V-V in FIG. 9A. FIG. 9D is a schematic view illustrating a non-conduction state in which the finger 8 makes no contact with the conductive rubber 16. FIG. 9E is a schematic view illustrating a conduction state in which the finger 8 presses against the conductive rubber 16.

As illustrated in FIGS. 9B and 9C, a portion of the conductive rubber 16 to which a pressure is applied by the finger 8 serves as a switch. A conduction area C is formed when the switch is recessed by a pressure applied to the conductive rubber 16. As illustrated in FIG. 9D, when the finger 8 makes no contact with the conductive rubber 16 or is just in contact with (or applies no pressure to) the conductive rubber 16, no current flows between the electrode 12A, the conductive rubber 16 and the electrode 12B. On the other hand, as illustrated in FIG. 9E, when the finger 8 presses against (or applies a pressure to) the conductive rubber 16, a current Ic flows between the electrode 12A, the conductive rubber 16 and the electrode 12B.

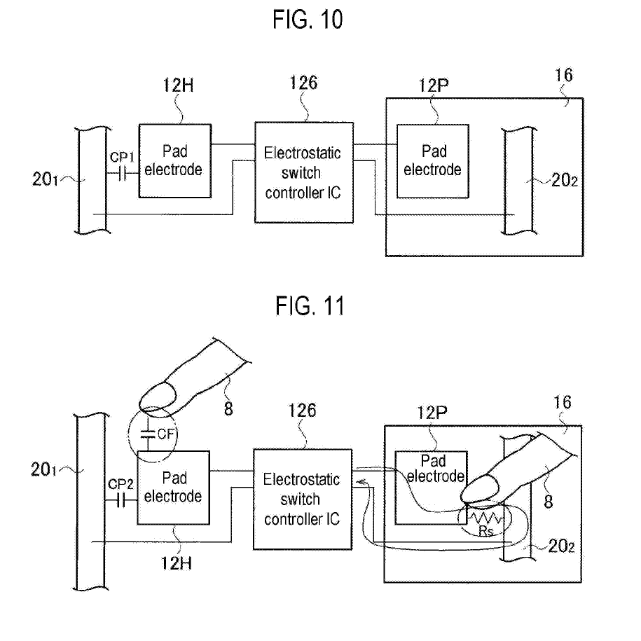

FIG. 10 is a schematic block diagram showing an example where a pad electrode 12H for sensing a contact to an electrostatic switch and a pad electrode 12P for sensing a pressure for the electrostatic switch are shared for the electrostatic switch controller according to the embodiment. As illustrated in FIG. 10, the electrostatic switch controller according to the embodiment includes an electrostatic switch control IC 126 connected to a wiring electrode 201 and a wiring electrode 202, a contact sensing pad electrode 12H and a pressure sensing pad electrode 12P connected to the electrostatic switch control IC 126, and a conductive rubber 16 formed on the pad electrode 120 and the wiring electrode 202 in the side of the pad electrode 12P. Although a single form of pad electrodes 12H and 12P is shown in FIG. 10, a plural form of pad electrodes 12H and 12P is arranged in actuality. In addition, individual pad electrodes 12P may be covered by their respective independent conductive rubbers 16 or a plurality of pad electrodes 12P may be covered by a single conductive rubber 16.

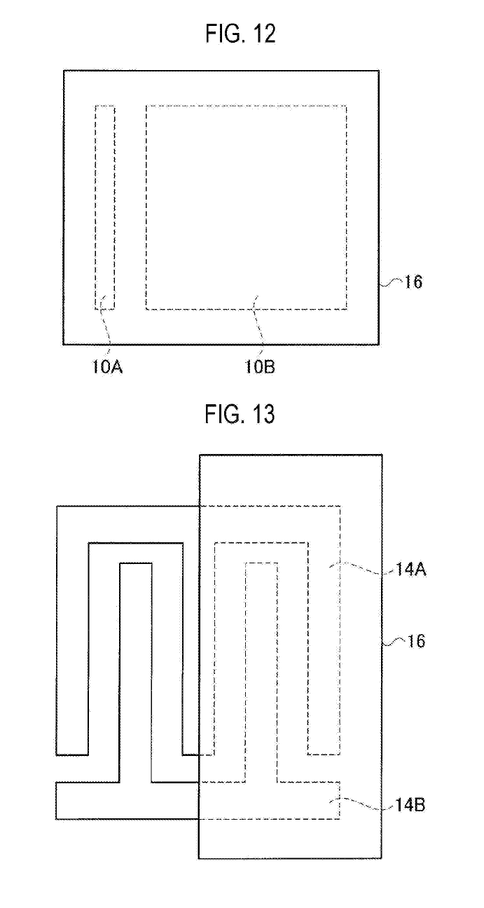

As illustrated in FIG. 11, as the finger 8 approaches the pad electrode 12H, a capacitance CF between the finger 8 and the pad electrode 12H is increased and a capacitance CP2 between the pad electrode 12H and the wiring electrode 201 is also increased. On the other hand, when the finger 8 presses against (applies a pressure to) the conductive rubber 16, a current flows into the pad electrode 12P via the conductive rubber 16 (with a resistance R_{S}). The electrostatic switch control IC 126 detects the resistance R_{S} in order to sense a pressure applied to the pad electrode 12P, whereas it detects the capacitance CP2 in order to sense the contact to the pad electrode 12H when no current flows into the pad electrode 12P. FIG. 12 shows an exemplary electrode pattern that shares the basic-sized electrodes 10A and 10B as illustrated in FIG. 2A. FIG. 13 shows an exemplary electrode pattern that shares the large-sized electrodes 14A and 14B as illustrated in FIG. 2C.

In this way, the electrostatic switch controller according to the embodiment uses the conductive rubber 16 to supplement the technique of the electrostatic switch. By sharing the pad electrode 12H for sensing the contact to the electrostatic switch and the pad electrode 12P for sensing the pressure for the electrostatic switch, it is possible to sense an event where a human body (such as a finger) approaches (becomes close to) or contacts the electrostatic switch and also sense a pressure (pressing) applied to the electrostatic switch. Therefore, it is possible to discriminate not only switch-on/off (contact/contactless) of the electrostatic switch but also a degree of contact (pressure) such as weak contact/strong contact.

According to this embodiment, since it is possible to detect not only the presence of contact to the sensor electrode but also the magnitude of pressure (pressing) applied to the sensor electrode, it is possible to sense with extremely high accuracy whether what contacts the sensor electrode is water such as raindrops, or a human body (for example, a finger).

### (Control Method of Electrostatic Switch According to Embodiment)

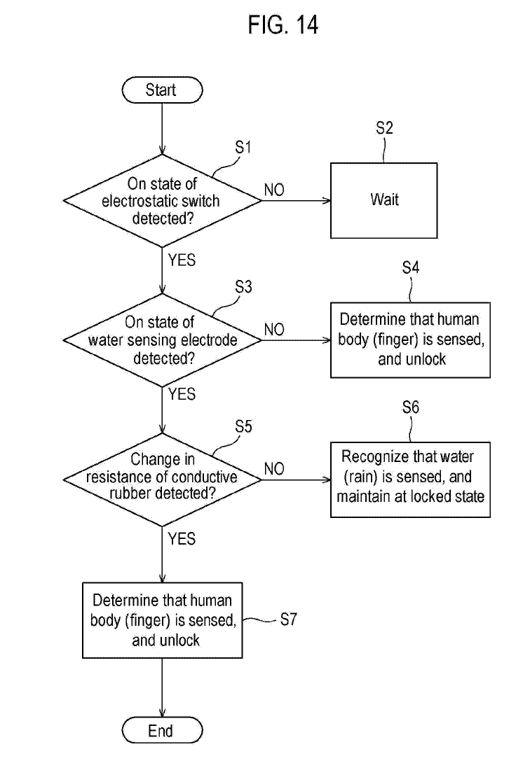

FIG. 14 illustrates a procedure of a control method of the electrostatic switch controller according to the embodiment. The electrostatic switch control IC 126 of the electrostatic switch controller according to the embodiment can realize processing operations of the electrostatic switch controller, the door operating device and the electronic key system including the electrostatic switch controller, which are capable of sensing a contact (approach) to an electrostatic switch and a degree of pressing (pressure) against the electrostatic switch at once while preventing erroneous sensing due to water droplets or the like attached to the electrostatic switch by controlling various parts of the electrostatic switch controller according to a procedure illustrated as follows.

First, at Step S1, the electrostatic switch control IC 126 detects whether or not the contact sensing sensor 132 of the electrostatic switch is turned on (i.e., detects a predetermined capacitance), i.e., whether or not something makes contact with the electrostatic switch. If the contact sensing sensor 132 is not turned on (i.e., does not detect the predetermined capacitance), i.e., if nothing makes contact with the contact sensing sensor 132, the electrostatic switch control IC 126 waits (Step S2).

If it is detected at Step S1 that the contact sensing sensor 132 of the electrostatic switch is turned on (i.e., detects the predetermined capacitance), i.e., that something makes contact with the contact sensing sensor 132, the procedure proceeds to Step S3.

Next, at Step S3, the electrostatic switch control IC 126 detects whether or not the rain sensing sensor 128 of the electrostatic switch is turned on (i.e., detects a predetermined capacitance), i.e., whether or not something makes contact with the electrostatic switch. If the raindrop sensing sensor 122 is not turned on (i.e., does not detect the predetermined capacitance), i.e., if nothing makes contact with the rain sensing sensor 128, the electrostatic switch control IC 126 determines that the electrostatic switch is in contact with a human body, not a raindrop, and then unlocks a door at Step S4.

Conversely, if it is detected at Step S3 that the rain sensing sensor 128 is turned on (i.e., detects the predetermined capacitance), i.e., that something makes contact with the rain sensing sensor 128, the procedure proceeds to Step S5.

Next, at Step S5, the electrostatic switch control IC 126 detects whether or not the pressure sensing sensor 136 of the electrostatic switch is turned on (i.e., detects a predetermined current (or resistance)), i.e., whether or not a pressure by a human body (such as a finger) is applied to the electrostatic switch. If the pressure sensing sensor 136 is not turned on (i.e., does not detect the predetermined current (or resistance)), i.e., if no pressure by a human body (such as a finger) is applied to the pressure sensing sensor 136, the electrostatic switch control IC 126 determines that the electrostatic switch is in contact with a raindrop, not the human body, and then maintains the door at a locked state at Step S6.

If it is detected at Step S5 that the rain sensing sensor 128 is turned on (i.e., detects a predetermined capacitance), i.e., that a pressure by the human body (such as a finger) is applied to the rain sensing sensor 128, the electrostatic switch control IC 126 determines that the electrostatic switch is in contact with the human body, not the raindrop, and then unlocks the door at Step S7.

Moreover, the predetermined capacitance detected at Step S1 is set to a value allowing a contact by a human body (such as a finger) to be sensed and the predetermined capacitance detected at Step S3 is set to a value allowing a contact by water such as a raindrop to be sensed and is substantially equal to the predetermined capacitance detected at Step S1. The predetermined current (or resistance) detected at Step S5 is set to a value allowing a pressure by a human body (such as a finger) to be sensed. In addition, since even a contact by water such as a raindrop applies a slight pressure, the value detected at Step S5 is set to be distinguished from the contact by water such as a raindrop.

(Example of Door Handle Provided with Door Operating Device)

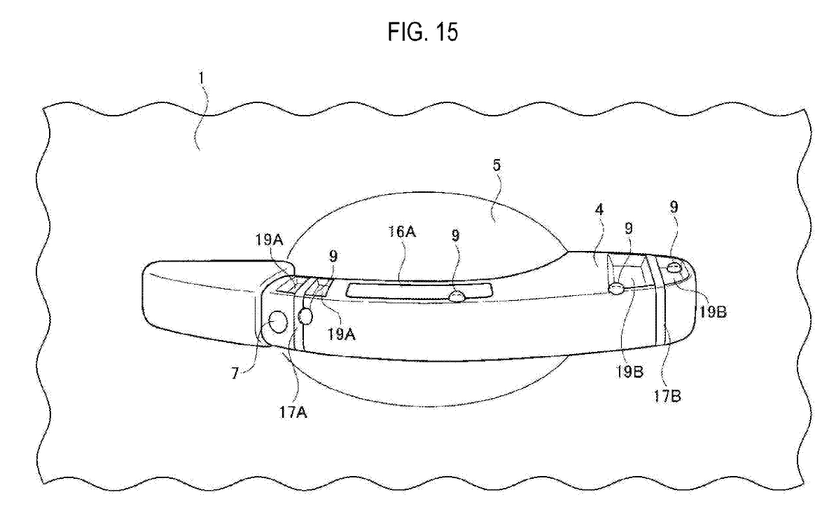

FIG. 15 is a schematic external view of an example of a door handle 4 having a door operating device including the electrostatic switch controller according to the embodiment. Electrodes 17A and 17B of the rain sensing sensor 128 are also arranged as shown in FIG. 15.

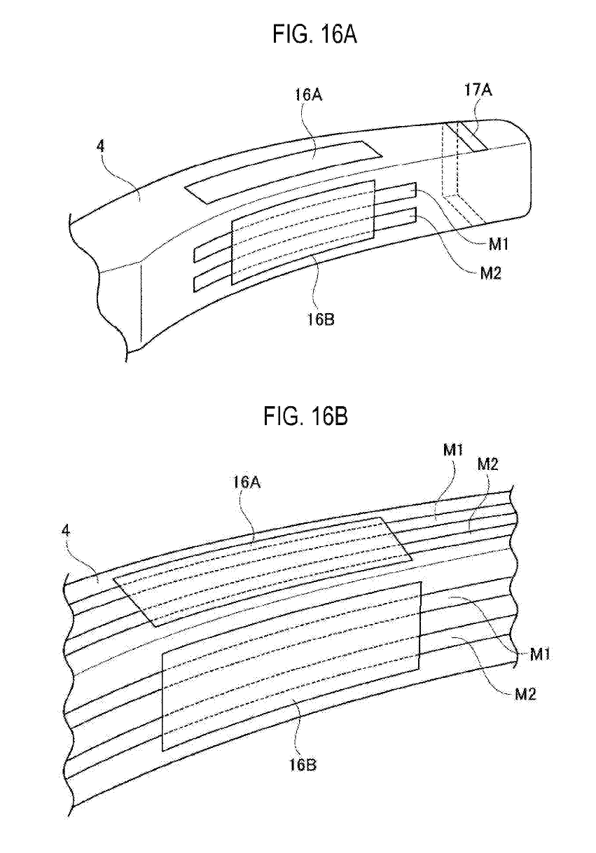

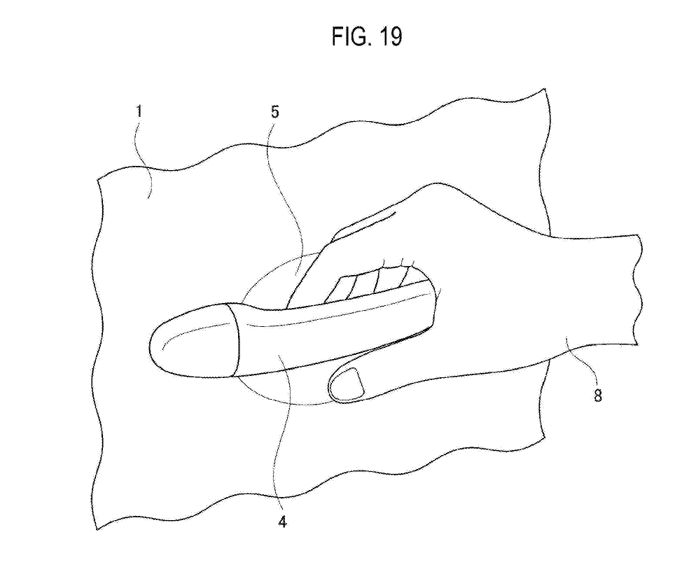

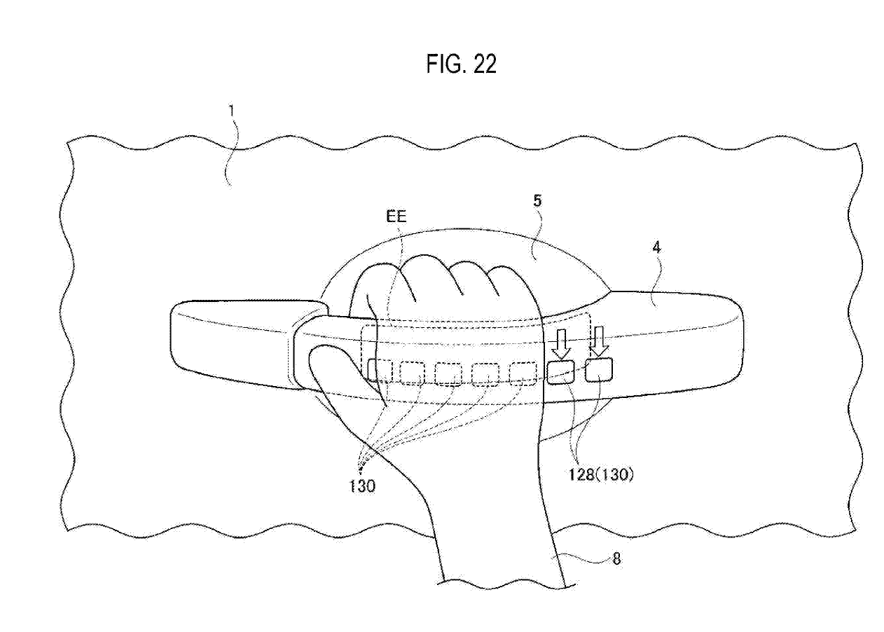

An example of a door handle 4 for vehicle will now be described with reference to FIG. 15. For example, raindrops 9 fall on (contact) the surface of the door handle 4 uniformly [Event P]. On the other hand, a person's hand 8 (not shown) contacts only a portion operated with the hand 8 (a rear portion of the door handle 4 on which fingers of the hand 9 are laid (see FIGS. 16A and 16B). For example, as illustrated in FIGS. 19 and 22, when the door handle 4 is operated, a recess 5 of the door is used to lay (contact) the fingers of the hand 8 on the inside rear portion) of the door handle 4 [Event Q]. FIG. 19 is a schematic view illustrating a situation where the door handle 4 provided with the door operating device according to the embodiment is operated with a right hand. FIG. 22 is a schematic external view of a door handle provided with a door operating device according to Modification 5 of the embodiment.

There are the following differences between Event P and Event Q. When the person's hand 8 is in contact with the door handle 4, there is a portion which becomes a shadow of the hand 9 in contact with the door handle 4 (that is, a portion preventing the raindrops 9 from falling as the hand 8 functions as an eave and covers a portion of the door handle 4) (see FIG. 19). Even when it is raining, the raindrops 9 are not laid on the portion which becomes the shadow (the portion where the hand 9 functions as an eave).

Therefore, in order to determine which is in contact, the raindrops 9 or the person's hand 8, the door operating device according to the embodiment includes at least two sensing sensors (the contact sensing part 120 (the contact sensing sensor 132 and the pressure sensing sensor 136)). The size, position, number of electrodes, shape, electrode-electrode distance, electrode-ground (GND) distance and the like of each of the sensing sensors of the contact sensing part 120) are adjusted as necessary.

In addition, in order to sense the contact of the raindrops 9 with high accuracy, recesses or grooves (grooves 19A and 19B in the example shown in FIG. 15) may be formed adjacent to the electrodes 17A and 17B of the rain sensing sensor 128 so that the raindrops 9 can be more easily gathered. Thus, while gathering the raindrops 9 more easily by forming the grooves 19A and 19B, it is possible to more reliably sense the contact of the raindrops 9 since the raindrops 9 can stay for a time required for the electrodes 17A and 17B of the rain sensing sensor 128 to sense the contact of the raindrops 9. Although it is illustrated in FIG. 15 that the grooves 19A and 19B are formed in the upper surface of the door handle 4 such that the grooves 19A and 19B are adjacent to the electrodes 17A and 17B, respectively, the present disclosure is not limited thereto. The size, shape, position, number and so on of the recesses or grooves can be appropriately adjusted in consideration of the size, shape and so on of the door handle 4 and the size, shape, position, sensitivity and so on of the electrodes 17A and 17B.

FIG. 16A is a schematic perspective view illustrating the rear side of the door handle 4 illustrated in FIG. 15. FIG. 16B is a partially-enlarged view of the rear side of the door handle 4 illustrated in FIG. 15. FIGS. 16A and 16B schematically illustrate the door handle 4 of a vehicle 1 equipped with the door operating device according to the embodiment, in which the contact sensing part 120 (the contact sensing sensor 132 and the pressure sensing sensor 136) is included in the door handle 4. Here, like FIG. 15, FIG. 16A also shows the electrode 17A of the rain sensing sensor 126.

For example, the door handle 4 is divided into three areas: an area in contact with the hand 8 (a first area in which the contact sensing sensor 132 and the pressure sensing sensor 136 having electrodes M1 and M2 covered by a conductive rubber 16B are arranged), an area which becomes a shadow as the hand 8 functions as an eave due to operation (action) of the hand 8 (an area on which the raindrops 9 are not laid) (a second area in which the contact sensing sensor 132 and the pressure sensing sensor 136 having electrodes M1 and M2 covered by a conductive rubber 16A are arranged), and an area on which the raindrops 9 are laid but which does not become a shadow since it is not affected by the hand 8 (a third area in which the electrodes 17A and 17B of the rain sensing sensor 128 are arranged).

In more detail, the first area of the door handle 4 is used to recognize (sense) contact of the hand 8 (for example, a right hand), the second area is used to determine (sense) a shadow by the hand 8, and the third area is used to recognize (sense) the raindrops 9.

### Modification 1

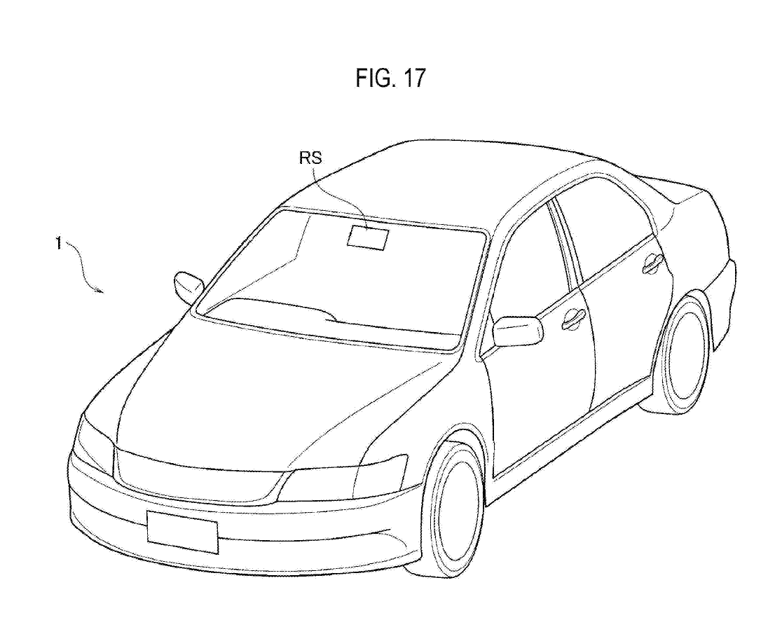

FIG. 17 schematically illustrates a vehicle 1 equipped with the door operating device according to the embodiment and further equipped with a raindrop sensing sensor RS located in the upper portion of the front of the vehicle 1 (in the vicinity of a room mirror of the vehicle 1). In this way, when the raindrop sensing sensor RS is additionally arranged at a position other than the door handle 4, it is possible to sense the raindrops with higher accuracy in cooperation with the raindrop sensing sensor 122 arranged in the door handle 4.

### Modification 2

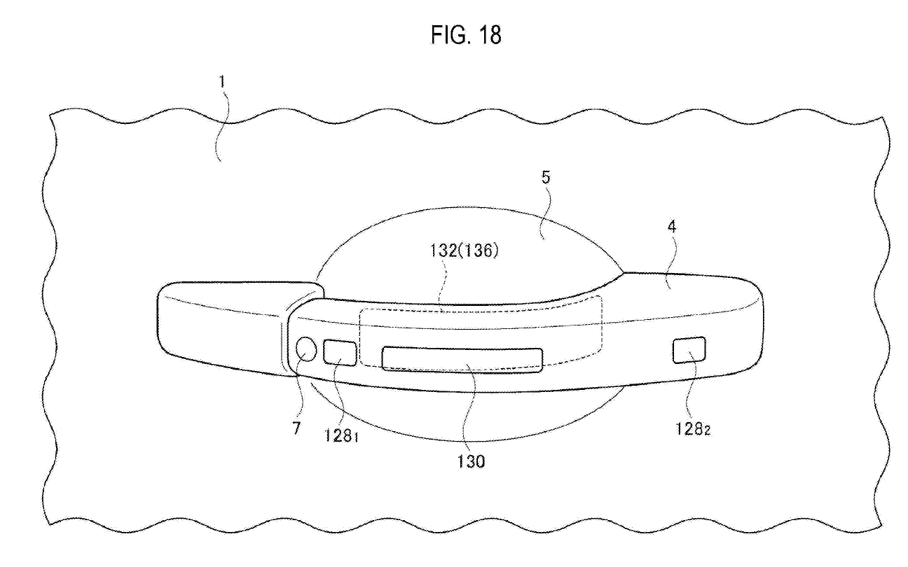

FIG. 18 schematically illustrates a door handle 4 equipped with a door operating device according to Modification 2 of the embodiment.

In the door handle 4 according to Modification 2, the clear weather sensing sensor 130 is arranged in the area which becomes a shadow as the hand 8 functions as an eave due to operation (action) of the hand 8 (the area on which the raindrops 9 are not laid). In addition, rain sensing sensors 128₁ and 128₂ are arranged in the area on which the raindrops 9 are laid but which does not become a shadow since it is not affected by the hand 8. In this way, when the rain sensing sensors 128 and the clear weather sensing sensor 130 are arranged together, it is possible to sense the raindrops with higher accuracy.

### Modification 3

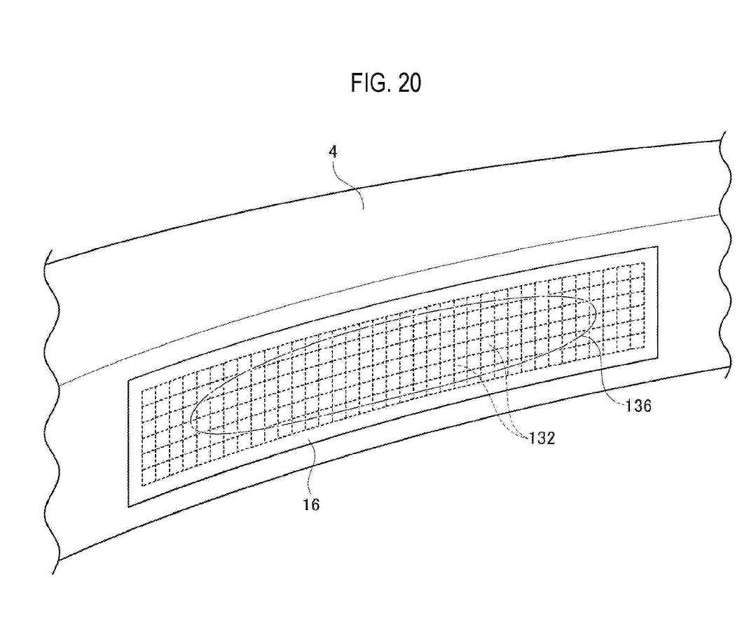

FIG. 20 schematically illustrates a contact sensing part 120 in the rear side of a door handle 4 according to Modification 3 of the embodiment. The contact sensing part 120 according to Modification 3 includes a plurality of contact sensing sensors 132 arranged in the form of a matrix. Then, a conductive rubber 16 is disposed to cover a portion of the plurality of contact sensing sensors 132 arranged in the form of a matrix and the portion covered by the conductive rubber 16 is constituted as the pressure sensing sensors 136. Thus, the contact sensing sensors 132 and the pressure sensing sensors 136 can be used in common.

### Modification 4

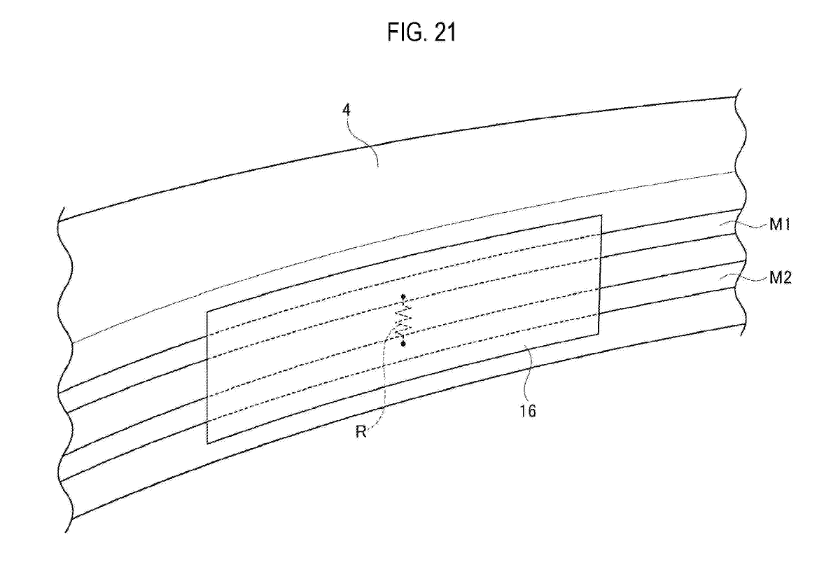

FIG. 21 schematically illustrates a contact sensing part 120 in the rear side of a door handle 4 according to Modification 4 of the embodiment. The contact sensing part 120 according to Modification 4 includes electrodes M1 and M2 of the contact sensing sensor 132 which are arranged in parallel. Then, a conductive rubber 16 is disposed to cover a portion of the electrodes arranged in parallel and the portion covered by the conductive rubber 16 is constituted as the pressure sensing sensor 136. The pressure sensing sensor 136 is able to detect a change in pressure by detecting a change in resistance R between the electrodes M1 and M2 of the contact sensing sensor 132. Thus, the contact sensing sensor 132 and the pressure sensing sensor 136 can be used in common.

### Modification 5

FIG. 22 is a schematic external view of a door handle having a door operating device according to Modification 5 of the embodiment.

The door handle 4 according to Modification 5 includes a plurality of raindrop sensing sensors 122 (rain sensing sensors 128 and clear weather sensing sensors 130). In this way, when the plurality of raindrop sensing sensors 122 (rain sensing sensors 128 and clear weather sensing sensors 130) is arranged, it is possible to sense the raindrops with higher accuracy. In this figure, two arrows schematically represent a situation where raindrops are laid on a particular rain sensing sensor 128 and a particular clear weather sensing sensor 130).

Although seven raindrop sensing sensors 122 are arranged in the example of FIG. 22, the number of raindrop sensing sensors 122 is not limited thereto.

In addition, the configurations of Modifications 1 to 5 may be used alone or two or more thereof may be used in combination.

### (Block Configuration of Electrostatic Switch Controller)

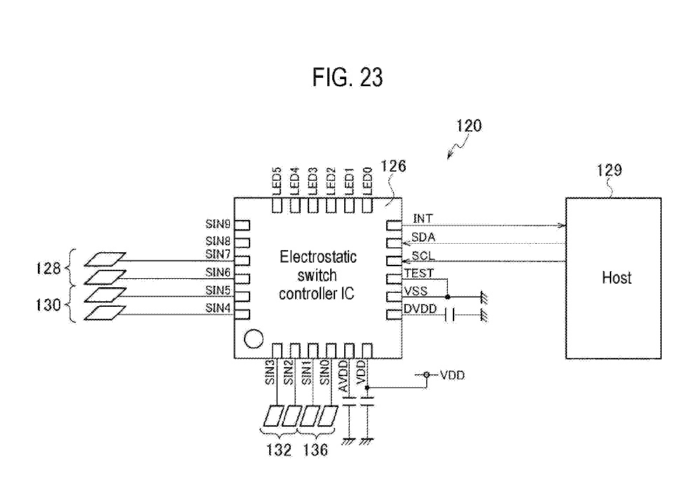

FIG. 23 is a schematic block diagram showing one example of an application circuit configuration of the electrostatic switch controller according to the embodiment.

As illustrated in FIG. 23, the application circuit configuration of the electrostatic switch controller includes an electrostatic switch control IC 126, rain sensing sensors 128, clear weather sensing sensors 130, contact sensing sensors 132 and pressure sensing sensors 136, all of these sensors being connected to the electrostatic switch control IC 126. The electrostatic switch control IC 126 is connected to a host device 129 such as an electronic device of an electronic key system to be described later.

The electrostatic switch control IC 126 is a controller of electrostatic capacitance sensors for switch operation, such as the rain sensing sensors 128, the clear weather sensing sensors 130, the contact sensing sensors 132 and the pressure sensing sensors 136.

The electrostatic switch control IC 126 may incorporate an AFE (Analog Front End) for detecting an electrostatic capacitance, an A/D converter for converting the detected capacitance into a digital detection value, an MPU (Micro Processing Unit) for processing the digital detection value, a PWM (Pulse Width Modulation) corresponding LED (Light Emitting Diode) controller, a two-line serial bus host interface corresponding to an I2C (Inter-Integrated Circuit) bus protocol, a power-on reset, a clock oscillation circuit, an internal LDO (Low Drop-Out regulator) and so on.

As illustrated in FIG. 23, in the electrostatic switch control IC 126, one electrostatic capacitance sensor can be used as one independent switch (that is, an independent sensing sensor (the rain sensing sensor 128, the clear weather sensing sensor 130, the contact sensing sensor 132 and/or the pressure sensing sensor 136). Each independent sensing sensor can recognize ON, OFF, long-pressing and so on.

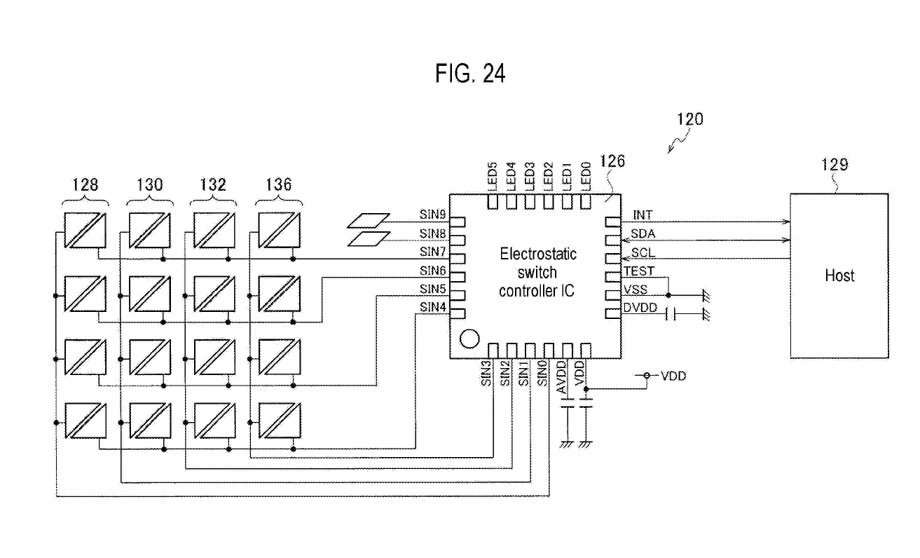

In addition, as illustrated in FIG. 24, in the electrostatic switch control IC 126, a plurality of sensors (rain sensing sensors 128, clear weather sensing sensors 130, contact sensing sensors 132 and/or pressure sensing sensors 136) may be arranged in the form of a matrix and each of the intersections (cross points) of the matrix arrangement may be treated as one key switch. Each intersection can recognize ON, OFF, long-pressing and so on.

### (Keyless Entry System)

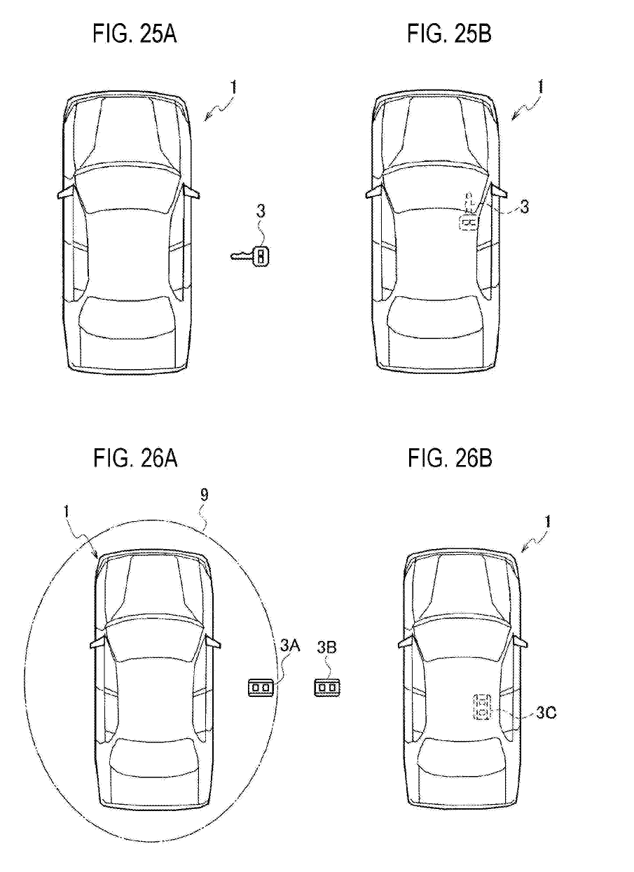

FIGS. 25A and 25B illustrate a situation of operating a vehicle 1 equipped with a general keyless entry system. When a door lock of the vehicle 1 using the keyless entry system is unlocked, as illustrated in FIG. 25A, a switch included in the body of an electronic key 3 is operated near the vehicle 1 to unlock the door lock. In addition, as illustrated in FIG. 25B, the engine of the vehicle 1 can be started by manually inserting and operating a key portion of the electronic key 3 into an ignition switch in the vehicle 1.

### (Electronic Key System)

FIGS. 26A and 26B illustrate a situation of operating a vehicle 1 equipped with a general electronic key system.

In operating the vehicle 1 equipped with the electronic key system, as illustrated in FIG. 26A, when a person (such as a driver) who carries (wears) an electronic key 3A falls within a range (operation range) which can receive a signal being transmitted from the vehicle 1, the electronic key 3A exchanges signals with the contactless sensing part 140 in the vehicle 1. Here, an electronic key out of the range (operation range) which can receive a signal being transmitted from the vehicle 1 is represented by an electronic key 3B which is the same as the electronic key 3A. If the engine of the vehicle 1 is stopped or the vehicle 1 is stopped, a door lock is unlocked only with contact of something to a contact sensing sensor placed in a door handle 4. In other words, the person who wears the electronic key 3A can unlock the door lock of the vehicle 1 without taking out the electronic key 3A.

In addition, as illustrated in FIG. 26B, the engine can also be started when an electronic key 3C exchanges signals with the contactless sensing part 140 within the operation range.

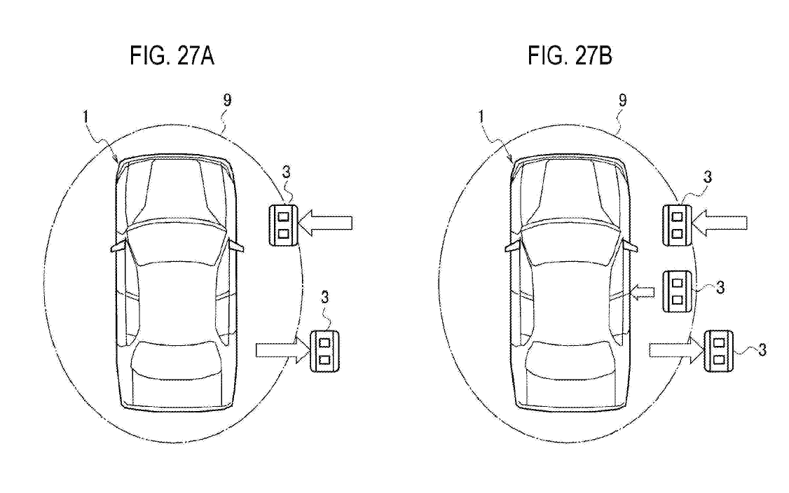

FIG. 27A illustrates a situation of operating a vehicle 1 equipped with an electronic key system according to a comparative example. In the vehicle 1 equipped with the electronic key system according to the comparative example, when a person who wears an electronic key 3 approaches the vehicle 1 and falls within an operation range, the electronic key 3 automatically exchanges signals with the vehicle 1, thereby unlocking a door lock of the vehicle 1.

On the other hand, FIG. 27B illustrates a situation of operating the vehicle 1 equipped with the electronic key system according to the embodiment. When the person who wears the electronic key 3 approaches the vehicle 1 and falls within the operation range, although the electronic key 3 automatically exchanges signals with the contactless sensing part 140 in the vehicle 1, the door lock of the vehicle 1 cannot be unlocked/locked by just that. When the person who wears the electronic key 3 approaches the vehicle 1, falls within the operation range and operates the door handle 4 (that is, contacts the contact sensing part 120 placed in the door handle 4) and the control part 200 performs the procedure as described above with reference to FIG. 14 and so on, it is possible to unlock the door lock of the vehicle 1 while preventing malfunction due to water droplet and the like.

### (Remote Door Lock System)

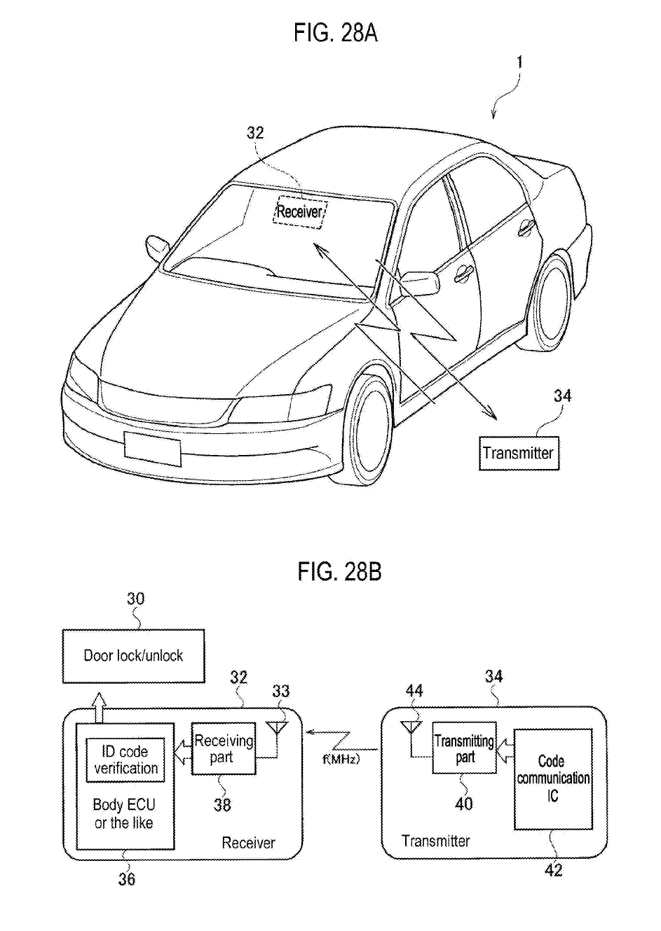

FIG. 28A schematically illustrates a remote door lock system in a vehicle 1 equipped with the electronic key system according to the embodiment. FIG. 28B is a schematic block diagram showing an exemplary configuration of the remote door lock system illustrated in FIG. 28A.

Here, while a normal door lock is unlocked/locked by operation of switches in/out of the vehicle 1, the remote door lock system in the vehicle 1 equipped with the electronic key system according to the embodiment unlocks/locks the door lock when the electronic key 3 having a remote function (transmitter 34) exchanges signals with the contactless sensing part 140 (receiver 32) of the vehicle 1. It is also possible to inform a driver or the like of a result of the unlock/lock of the door lock, such as by lighting of a hazard lamp of the vehicle 1. The door lock may include a door lock of a cargo compartment (such as a trunk) in addition to a door for a person to get on/off.

The transmitter 34 of the electronic key 3 includes a transmitting part 40, a code communication IC 42 and an antenna 44. The receiver 32 of the contactless sensing part 140 of the vehicle 1 includes a receiving part 38, an ECU (Electronic Control Unit) 36 and an antenna 33. The ECU 36 is connected to an unlock/lock part (unlock/lock device) 30.

An ID code, which is coded in the code communication IC 42 of the transmitter 34 and transmitted from the transmitting part 40 to the antenna 44, is received in the receiving part 38 of the receiver 32 via the antenna 33. The received ID code is demodulated and collated in the ECU 36. If this ID code is authenticated as formal, the ECU 36 instructs the unlock/lock part 30 to perform the unlock/lock operation.

(Method of Operating Vehicle Equipped with Electronic Key System)

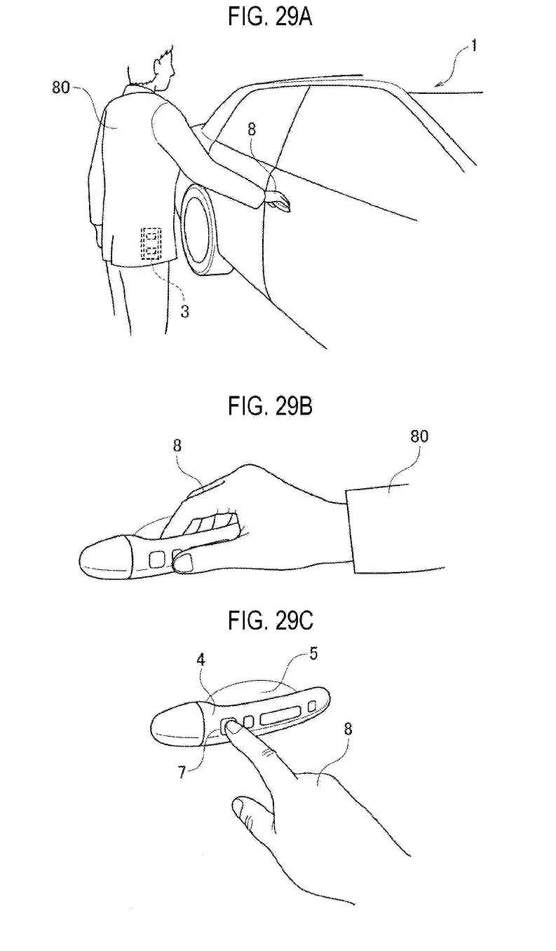

FIG. 29A is a schematic view illustrating a situation of operating a vehicle 1 equipped with the electronic key system according to the embodiment. FIG. 29B is a schematic view illustrating a situation of operating a door handle 4 of the vehicle 1 illustrated in FIG. 29A. FIG. 29C is a schematic view illustrating a situation of operating a button switch 7 installed in the door handle 4 illustrated in FIG. 29B.

In the vehicle 1 equipped with the electronic key system according to the embodiment, a person (such as a driver) 80 who carries (wears) the electronic key 3 can unlock/lock the door lock of the vehicle 1 without taking out the electronic key 3. As illustrated in FIG. 29A, when the person 80 who wears the electronic key 3 falls within an operation range, the electronic key 3 exchanges (coded) signals with the contactless sensing part 140. If an ID code transmitted from the electronic key 3 is authenticated as formal by the contactless sensing part 140 of the vehicle 1, as illustrated in FIG. 29B, the door lock can be unlocked with only contact of the hand 8 (for example, a finger) of the person 80 to the contact sensing sensor 132 and pressure sensing sensor 136 arranged in the door handle 4.

In locking the door lock, under a state where the door is closed, when the person 80 who wears the electronic key 3 presses the button switch 7 placed in the door handle 4 with the hand 8 (for example, a finger), the electronic key 3 exchanges (coded) signals with the contactless sensing part 140. When the ID code transmitted from the electronic key 3 is authenticated as normal by the contactless sensing part 140 of the vehicle 1 and it is checked that the electronic key 3 is not left behind in the interior of the vehicle 1, the door lock is locked. With the electronic key 3 left in the interior of the vehicle 1, even when the button switch 7 is operated, the door lock is not locked in order to prevent containment of the electronic key 3 and the person is warned with an alarm or the like.

### (Configuration of Electronic Key System)

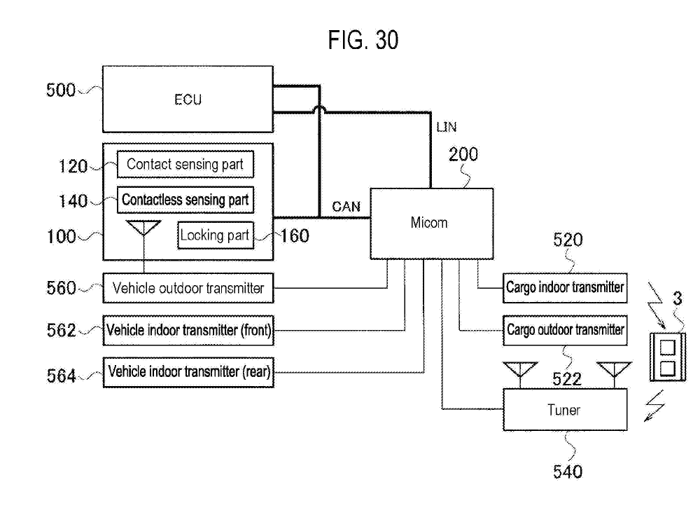

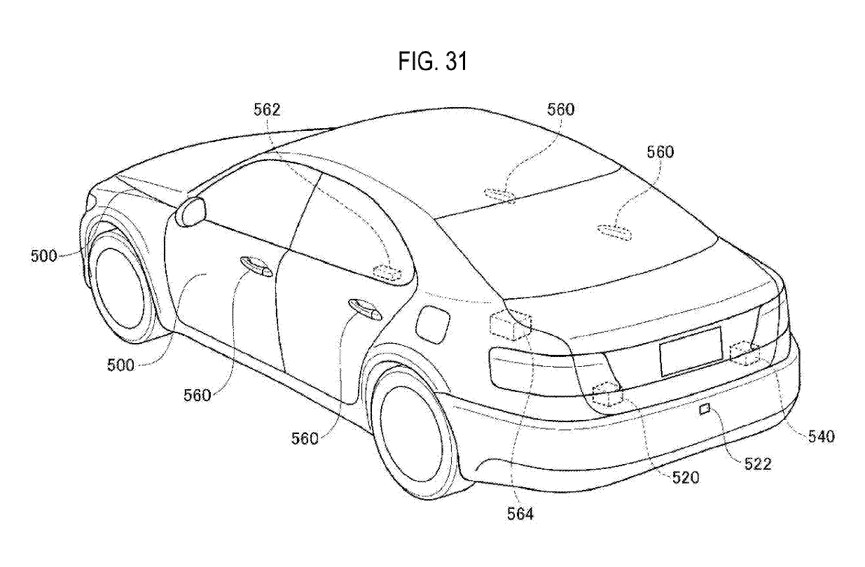

FIG. 30 is a schematic block diagram showing an exemplary configuration of the electronic key system according to the embodiment. FIG. 31 schematically shows one example of a vehicle equipped with various parts of the electronic key system illustrated in FIG. 30.

The electronic key system according to the embodiment includes an ECU (Electronic Control Unit) 500, an opening/closing mechanism part 100 includes a contact sensing part 120, a contactless sensing part 140 and a locking part 160, a vehicle outdoor transmitter 560, a vehicle indoor transmitter (front) 562 and a vehicle indoor transmitter (rear) 564, which are respectively arranged in the front and rear of the vehicle, a cargo indoor transmitter 520, a cargo outdoor transmitter 522, a tuner 540, and a control part (microcomputer) 200 for connecting to and controlling the above-mentioned parts in the electronic key system. The control part (microcomputer) 200 controls the ECU 500 and the opening/closing mechanism part 100 via an onboard network such as CAN (Controller Area Network) or LIN (Local Interconnect Network).

In the electronic key system according to the embodiment, the control part 200 performs the following control for ID verification between the electronic key 3 and the vehicle 1, location identification of the electronic key 3, and so on. First, the control part 200 transmits a request signal for the ID verification and the location identification to the electronic key 3 via each transmitter (the vehicle outdoor transmitter 560, vehicle indoor transmitter (front) 562, vehicle indoor transmitter (rear) 564, cargo indoor transmitter 520, and cargo outdoor transmitter 522). Next, the control part 200 receives a response signal containing an ID code and the like from the electronic key 3 which received the request signal. Based on the received response signal, the control part 200 makes an ID verification and instructs the ECU 500 and the opening/closing mechanism part 100 to perform an operation.

The electronic key 3 may include a lock/unlock switch, a cargo switch and the like through which respective doors can be locked/unlocked. In addition, the electronic key 3 may further include a lock/unlock key or transponder key for emergency.

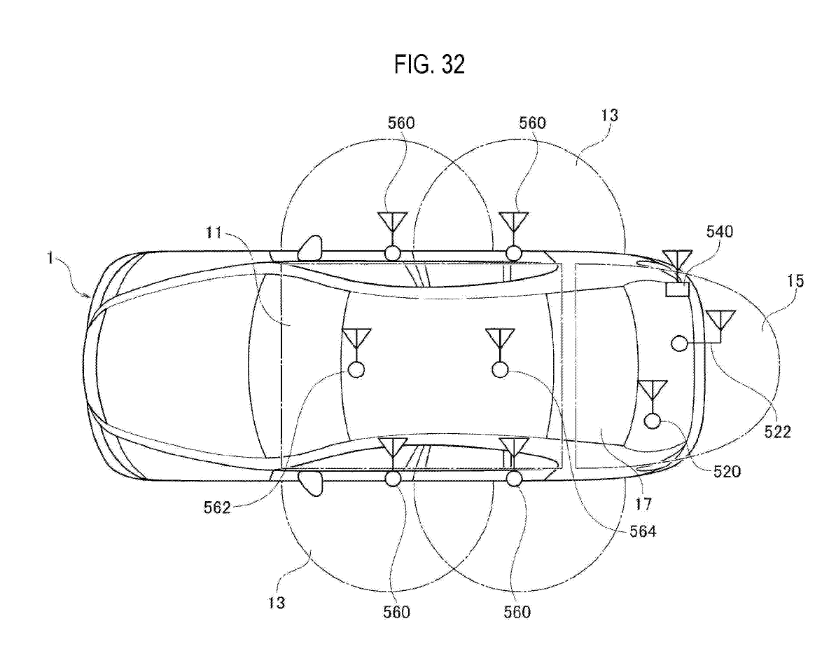

FIG. 32 schematically shows an exemplary sensing range of the electronic key system according to the embodiment. A sensing range of the electronic key 3, which is transmitted from the control part 200 via each transmitter (the vehicle outdoor transmitter 560, vehicle indoor transmitter (front) 562, vehicle indoor transmitter (rear) 564, cargo indoor transmitter 520, and cargo outdoor transmitter 522), is formed from a vehicle indoor sensing area 11, vehicle outdoor sensing area 13, cargo outdoor sensing area 15, and cargo indoor sensing area 17. The vehicle indoor sensing area 11 is formed to perform controls of opening/closing of a door of a driver's seat, a brake, an ignition key, various alarms and the like. The vehicle outdoor sensing area 13 is formed for ID verification and location identification of the electronic key 3 at the time of locking/unlocking the door lock in the interior of the vehicle. The cargo outdoor sensing area 15 is formed for ID verification and location identification of the electronic key 3 at the time of locking/unlocking the door lock of the cargo door. The cargo indoor sensing area 17 is formed to open/close the cargo door.

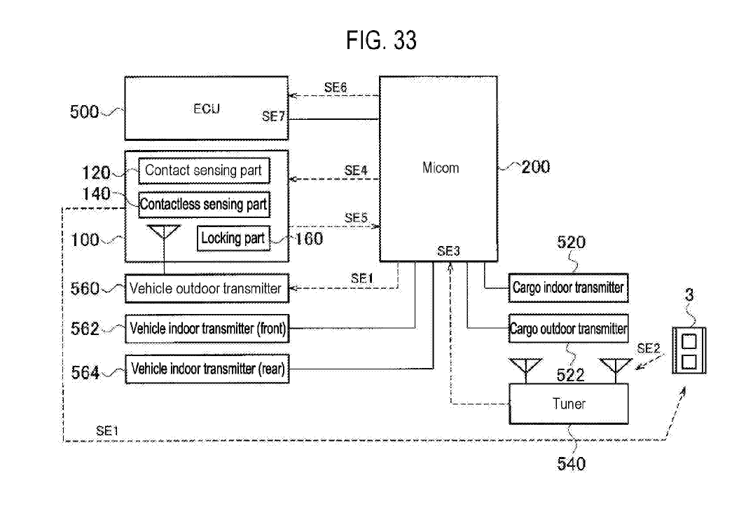

FIG. 33 schematically shows an exemplary control at the time of unlocking a door in the electronic key system according to the embodiment.

As illustrated in FIG. 33, the control part 200 intermittently transmits a signal from an antenna via the vehicle outdoor transmitter 560 (SE1). When the person who wears the electronic key 3 approaches the vehicle 1 and falls within a range of the vehicle outdoor sensing area 13 and the electronic key 3 receives a signal from the vehicle outdoor transmitter 560, the electronic key 3 transmits a signal containing data such as an ID code to the vehicle 1 (SE2). The control part 200 receives the signal, which is transmitted from the electronic key 3, via the tuner 540 (SE3). Verification of the ID code is performed based on the received signal. If the ID code is authenticated, the control part 200 sends an instruction for operation standby to the contact sensing part 120 (SE4). Upon sensing no contact by the raindrops 9 as the person's hand 8 is in contact with the human body sensing sensor 124, the contact sensing part 120 reports the sensing information to the control part 200 (SE5). In response to this, the control part 200 transmits a door lock unlocking instruction signal to the ECU 500 (SE6). According to the received door lock unlocking instruction signal, the ECU 500 instructs the locking part 160 to unlock the lock of the locking device (SE7).

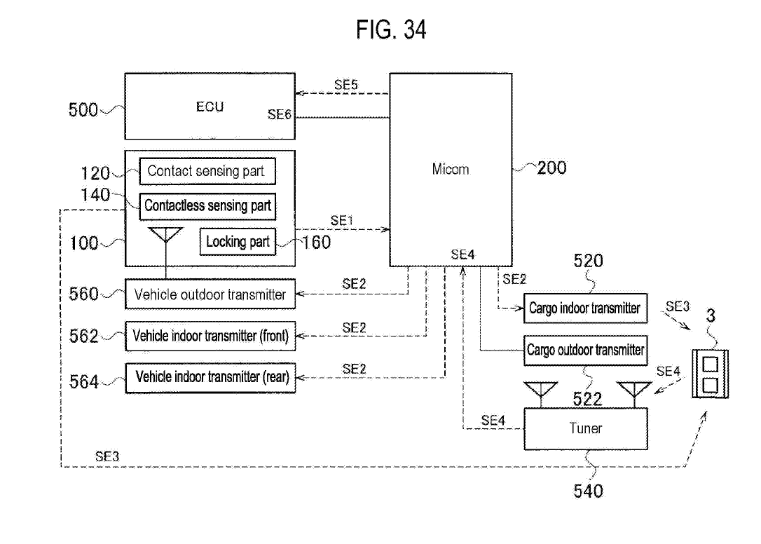

FIG. 34 schematically shows an exemplary control at the time of locking a door in the electronic key system according to the embodiment.

As illustrated in FIG. 34, under a state where the engine is stopped and all doors are closed, when the button switch 7 of the door handle 4 is pressed by the person's hand 8 (SE1), the control part 200 transmits a request signal to each transmitter (the vehicle outdoor transmitter 560, vehicle indoor transmitter (front) 562, vehicle indoor transmitter (rear) 564, and cargo indoor transmitter 520) (SE2). In response to the received request signal, each transmitter (the vehicle outdoor transmitter 560, vehicle indoor transmitter (front) 562, vehicle indoor transmitter (rear) 564, and cargo indoor transmitter 520) forms the vehicle indoor sensing area 11, vehicle outdoor sensing area 13, cargo outdoor sensing area 15, and cargo indoor sensing area 17 and reports the fact to the electronic key 3 (SE3). The electronic key 3 transmits a signal containing data such as an ID code to the vehicle 1 (SE4). The control part 200 receives the signal, which is transmitted from the electronic key 3, via the tuner 540 and performs verification of the ID code based on the received signal. When the control part 200 authenticates the ID code and checks that the electronic key 3 is not present within the vehicle (i.e., is out of the vehicle), the control part 200 transmits a door lock locking instruction signal to the ECU 500 (SE5). According to the received door lock locking instruction signal, the ECU 500 instructs the locking part 160 to lock the lock of the locking device (SE6).

### (Electronic Device)

The contact sensing part 120 (electrostatic switch controller) of the door operating device according to the embodiment can be applied to various electronic devices such as the host device 129 illustrated in FIGS. 23 and 24. That is, since the contact sensing part 120 (electrostatic switch controller) employs an electrostatic switch with a simple structure, which is robust (i.e., does not malfunction) to water (rain), is inexpensive and has good operability, it can be applied to various electronic devices as well as a door knob 2 and a door handle 4. In addition, the use of the contact sensing part 120 (electrostatic switch controller) is not limited to door opening/closing. For example, the contact sensing part 120 may be used for various operations (such as instruction and authentication), including operating switches, buttons and touch panels of various electronic devices. For example, the contact sensing part 120 (electrostatic switch controller) or the contact sensing part 120 (electrostatic switch controller)/the electrostatic switch control IC 126 can be applied to a mobile phone, a smartphone, a tablet PC, a camera, a PDA (Personal Digital Assistant), a digital audio player, a portable game machine, a copy machine, a facsimile, a car navigation and the like, including those highly pubic which are handled by many and unspecified number of people, such as ATMs of financial institutions such as banks, vending machines (particularly, ticket machines in railway stations and restaurants) and the like. Furthermore, the contact sensing part 120 (electrostatic switch controller) or the contact sensing part 120 (electrostatic switch controller)/the electrostatic switch control IC 126 can be also applied to a multimedia station, an arcade game, a guide board, a job search system of Hello Work, an order system in food service restaurants, an automatic checkout machine, an automatic voting machine, a library lending system, a cash register system, a scoring system, a railway vehicle monitoring device, an electronic musical instrument and the like.

According to this embodiment, it is possible to provide an electrostatic switch controller, a control method thereof, a door operating device, and an electronic key system, which are capable of sensing contact (approaching) and pressing at once while preventing erroneous water (rain) sensing of an electrostatic switch.

According to this embodiment, it is possible to provide an electrostatic switch controller, a control method thereof, a door operating device, and an electronic key system, which are capable of preventing malfunction due to water or the like by dividing a discrimination portion of a contact sensing part according to specified conditions in door knobs (indoor and outdoor) having an electrostatic-typed lock and door handles.

### Other Embodiment

As described above, the present disclosure has been illustrated by way of some embodiments, but the description and drawings which constitute a part of this disclosure are exemplary and should not be construed to limit the present disclosure. Various alternative embodiments, examples and operation techniques will be apparent to those skilled in the art from this disclosure.

Thus, the present disclosure includes other different embodiments which are not described herein.

### INDUSTRIAL APPLICABILITY

The electrostatic switch controller, the control method thereof, the door operating device and the electronic key system according to this embodiment can be applied to doors in buildings, vehicles, and so on.

According to the present disclosure in some embodiments, it is possible to provide an electrostatic switch controller, a control method thereof, a door operating device, and an electronic key system, which are capable of sensing a contact (approach) to an electrostatic switch and a degree of pressing (pressure) against the electrostatic switch at once while preventing erroneous sensing due to water droplets or the like attached to the electrostatic switch.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An electrostatic switch controller, comprising:
a contact sensing sensor configured to sense presence of contact of a person to a contact portion when the person performs an operation;
a pressure sensing sensor configured to sense a pressure applied to the contact portion; and
a control part configured to determine whether the contact to the contact portion is made by at least a portion of a body of the person, based on a result of the sensing by the contact sensing sensor and the pressure sensing sensor.

2. The electrostatic switch controller of claim 1, wherein the control part is further configured to determine that the contact to the contact portion is made by a raindrop, based on a result of the sensing by the contact sensing sensor and the pressure sensing sensor.

3. The electrostatic switch controller of claim 2, further comprising a rain sensing sensor configured to sense a contact of the raindrop.

4. The electrostatic switch controller of claim 1, wherein the contact sensing sensor includes:
a substrate; and
an electrostatic capacitance type sensing electrode formed on the substrate.

5. The electrostatic switch controller of claim 1, wherein the pressure sensing sensor includes:
a substrate;
an electrostatic capacitance type sensing electrode formed on the substrate; and
a conductive rubber disposed to cover at least a portion of the sensing electrode.

6. The electrostatic switch controller of claim 1, wherein at least one of the contact sensing sensor or the pressure sensing sensor comprises an electrostatic capacitance sensor.

7. The electrostatic switch controller of claim 6, wherein at least one of the contact sensing sensor or the pressure sensing sensor comprises electrostatic capacitance sensors arranged in a form of a matrix.

8. The electrostatic switch controller of claim 3, wherein at least one of the contact sensing sensor, the pressure sensing sensor or the rain sensing sensor comprises an electrostatic capacitance sensor.

9. The electrostatic switch controller of claim 8, wherein at least one of the contact sensing sensor, the pressure sensing sensor or the rain sensing sensor comprises electrostatic capacitance sensors arranged in a form of a matrix.

10. A control method of an electrostatic switch controller including a contact sensing sensor configured to sense presence of contact of a person to a contact portion when the person performs an operation, a pressure sensing sensor configured to sense a pressure applied to the contact portion, and a control part configured to determine whether the contact to the contact portion is made by at least a portion of a body of the person, based on a result of the sensing by the contact sensing sensor and the pressure sensing sensor, the control method comprising:
by the contact sensing sensor, sensing presence of a contact to the contact portion;
by the pressure sensing sensor, sensing a pressure applied to the contact portion; and
by the control part, determining whether the contact to the contact portion is made by at least a portion of a body of the person, based on a result of the sensing by the contact sensing sensor and the pressure sensing sensor.

11. The control method of claim 10, further comprising: by the control part, determining that the contact to the contact portion is made by a raindrop, based on a result of the sensing by the contact sensing sensor and the pressure sensing sensor.

12. A door operating device comprising:
an electrostatic switch controller including a contact sensing part including a contact sensing sensor configured to sense presence of contact of a person to a contact portion when the person performs an opening or a closing operation for a door and a pressure sensing sensor configured to sense a pressure applied to the contact portion;
a locking part configured to unlock and lock the door; and
a control part configured to instruct the locking part to unlock the door when determining that the contact to the contact portion is made by at least a portion of a body of the person, based on a result of the sensing by the contact sensing sensor and the pressure sensing sensor.

13. The door operating device of claim 12, wherein the control part is further configured to instruct the locking part to lock the door when determining that the contact to the contact portion is made by a raindrop, based on a result of the sensing by the contact sensing sensor and the pressure sensing sensor.

14. The door operating device of claim 13, further comprising a rain sensing sensor configured to sense a contact by the raindrop.

15. The door operating device of claim 12, further comprising a contactless sensing part including a signal transmitting/receiving section configured to transmit/receive a signal to/from an electronic key carried by the person, and a key recognizing section configured to recognize the electronic key and an operation of the electronic key based on the signal transmitted/received by the signal transmitting/receiving section,
wherein the control part is further configured to control the locking part based on the result of the sensing by the contact sensing sensor and the pressure sensing sensor and a result of the recognition by the key recognizing section.

16. The door operating device of claim 12, wherein the contact sensing sensor includes:
a substrate; and
an electrostatic capacitance type sensing electrode formed on the substrate.

17. The door operating device of claim 12, wherein the pressure sensing sensor includes:
a substrate;
an electrostatic capacitance type sensing electrode formed on the substrate; and
a conductive rubber disposed to cover at least a portion of the sensing electrode.

18. The door operating device of claim 14, wherein at least one of the contact sensing sensor, the pressure sensing sensor or the rain sensing sensor comprises an electrostatic capacitance sensor.

19. The door operating device of claim 18, wherein at least one of the contact sensing sensor, the pressure sensing sensor or the rain sensing sensor comprises electrostatic capacitance sensors arranged in a form of a matrix.

20. An electronic key system comprising:
an electrostatic switch controller including a contact sensing part including a contact sensing sensor configured to sense presence of contact of a person to a contact portion when the person performs an opening or a closing operation for a door, and a pressure sensing sensor configured to sense a pressure applied to the contact portion;
a locking part configured to unlock and lock the door;
a transmitter configured to form a sensing range of an electronic key carried by the person; and
a control part configured to recognize the electronic key within the sensing range and an operation of the electronic key and instruct the locking part to unlock the door when determining that the contact to the contact portion is made by at least a portion of a body of the person, based on a result of the sensing by the contact sensing sensor and the pressure sensing sensor.

21. The electronic key system of claim 20, wherein the control part is further configured to instruct the locking part to lock the door when determining that the contact to the contact portion is made by a raindrop, based on a result of the sensing by the contact sensing sensor and the pressure sensing sensor.

22. The electronic key system of claim 21, further comprising a rain sensing sensor configured to sense a contact by the raindrop.

23. The electronic key system of claim 20, further comprising a contactless sensing part including a signal transmitting/receiving section configured to transmit/receive a signal to/from an electronic key carried by the person, and a key recognizing section configured to recognize the electronic key and an operation of the electronic key based on the signal transmitted/received by the signal transmitting/receiving section,
wherein the control part is further configured to control the locking part based on the result of the sensing by the contact sensing sensor and the pressure sensing sensor and a result of the recognition by the key recognizing section.

24. The electronic key system of claim 20, wherein the contact sensing sensor includes:
a substrate; and
an electrostatic capacitance type sensing electrode formed on the substrate.

25. The electronic key system of claim 20, wherein the pressure sensing sensor includes:
a substrate;
an electrostatic capacitance type sensing electrode formed on the substrate; and
a conductive rubber disposed to cover at least a portion of the sensing electrode.

26. The electronic key system of claim 22, wherein at least one of the contact sensing sensor, the pressure sensing sensor or the rain sensing sensor comprises an electrostatic capacitance sensor.

27. The electronic key system of claim 26, wherein at least one of the contact sensing sensor, the pressure sensing sensor or the rain sensing sensor comprises electrostatic capacitance sensors arranged in a form of a matrix.
